(19) United States
(12) Patent Application Publication
(10) Pub. No.: US 2025/0048680 A1
(43) Pub. Date: Feb. 6, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP)

(73) Assignee: Japan Display Inc., Tokyo (JP)

(21) Appl. No.: 18/898,825

(22) Filed: Sep. 27, 2024

Related U.S. Application Data
(63) Continuation of application No. PCT/JP2023/009642, filed on Mar. 13, 2023.

(30) Foreign Application Priority Data
Mar. 30, 2022 (JP) 2022-057462

(51) Int. Cl. H01L 29/786; H01L 29/66

(52) U.S. Cl. CPC H01L 29/78603; H01L 29/78648; H01L 29/7869; H01L 29/66742

(57) ABSTRACT

A semiconductor device includes a substrate, an insulating layer over the substrate, a metal oxide layer over the insulating layer, and an oxide semiconductor layer over the metal oxide layer. The insulating layer includes a first region overlapping the metal oxide layer and a second region not overlapping the metal oxide layer. A hydrogen concentration of the first region is greater than a hydrogen concentration of the second region. A nitrogen concentration of the first region is greater than a nitrogen concentration of the second region.

### CROSS-REFERENCE TO RELATED APPLICATIONS

This application is a Continuation of International Patent Application No. PCT/JP2023/009642, filed on Mar. 13, 2023, which claims the benefit of priority to Japanese Patent Application No. 2022-057462, filed on Mar. 30, 2022, the entire contents of which are incorporated herein by reference.

### FIELD

An embodiment of the present invention relates to a semiconductor device. In particular, an embodiment of the present invention relates to a semiconductor device using an oxide semiconductor as a channel.

### BACKGROUND

In recent years, instead of a silicon semiconductor layer using amorphous silicon, low-temperature polysilicon, and single-crystal silicon, a semiconductor device in which an oxide semiconductor layer is used for a channel has been developed (for example, see Japanese laid-open patent publication Nos. 2021-141338, 2014-099601, 2021-153196, 2018-006730, 2016-184771, and 2021-108405). The semiconductor device including an oxide semiconductor layer can be fabricated with a simple structure and low-temperature process, similar to a semiconductor device including an amorphous silicon layer. Further, the semiconductor device including an oxide semiconductor layer is known to have higher mobility than the semiconductor device including an amorphous silicon layer.

It is essential to supply oxygen to an oxide semiconductor layer in the manufacturing process and to reduce the oxygen deficiencies formed in the oxide semiconductor layer in order for the semiconductor device in which the oxide semiconductor is used for the channel to perform a stable operation. For example, a technique of forming an insulating layer covering the oxide semiconductor layer under the condition that the insulating layer contains more oxygen is disclosed as one method of supplying oxygen to the oxide semiconductor layer.

### SUMMARY

A semiconductor device according to an embodiment of the present invention includes a substrate, an insulating layer over the substrate, a metal oxide layer over the insulating layer, and an oxide semiconductor layer over the metal oxide layer. The insulating layer includes a first region overlapping the metal oxide layer and a second region not overlapping the metal oxide layer. A hydrogen concentration of the first region is greater than a hydrogen concentration of the second region. A nitrogen concentration of the first region is greater than a nitrogen concentration of the second region.

### BRIEF DESCRIPTION OF DRAWINGS

FIG. 1 is a cross-sectional view showing an overview of a semiconductor device according to an embodiment of the present invention.

FIG. 2 is a plan view showing an overview of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a sequence diagram showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

FIG. 19 is a cross-sectional view showing a method for manufacturing a semiconductor device according to an embodiment of the present invention.

FIG. 20 is a cross-sectional view showing a method for manufacturing a semiconductor device according to an embodiment of the present invention.

FIG. 21 is a cross-sectional view showing a method for manufacturing a semiconductor device according to an embodiment of the present invention.

FIG. 22 is a plan view showing an overview of a display device according to an embodiment of the present invention.

FIG. 23 is a block diagram showing a circuit configuration of a display device according to an embodiment of the present invention.

FIG. 24 is a circuit diagram showing a pixel circuit of a display device according to an embodiment of the present invention.

FIG. 25 is a cross-sectional view showing an overview of a display device according to an embodiment of the present invention.

FIG. 26 is a plan view of a pixel electrode and a common electrode of a display device according to an embodiment of the present invention.

FIG. 27 is a circuit diagram showing a pixel circuit of a display device according to an embodiment of the present invention.

FIG. 28 is a cross-sectional view showing an overview of a display device according to an embodiment of the present invention.

FIG. 29 is a graph showing a measurement result of a SIMS analysis of a source region or a drain region of an oxide semiconductor layer of a semiconductor device.

FIG. 30 is a graph showing a measurement result of a SIMS analysis of a source region or a drain region of an oxide semiconductor layer of a semiconductor device.

FIG. 31A shows graphs of electrical characteristics of semiconductor devices having different channel lengths and channel widths in an example.

FIG. 31B shows graphs of electrical characteristics of semiconductor devices having different channel lengths and channel widths in an example.

FIG. 31C shows graphs of electrical characteristics of semiconductor devices having different channel lengths and channel widths in an example.

FIG. 31D shows graphs of electrical characteristics of semiconductor devices having different channel lengths and channel widths in an example.

FIG. 31E shows graphs of electrical characteristics of semiconductor devices having different channel lengths and channel widths in an example.

### DESCRIPTION OF EMBODIMENTS

An insulating layer formed with more oxygen-containing conditions contains more defects. As a result, abnormal characteristics of the semiconductor device or a variation in characteristics in a reliability test occur, which are considered to be caused by electrons becoming trapped in the defect. On the other hand, when an insulating layer with fewer defects is used, oxygen in the insulating layer cannot be increased. Therefore, sufficient oxygen cannot be supplied from the insulating layer to the oxide semiconductor layer. As described above, there is a demand for realizing a structure capable of repairing oxygen deficiencies formed in the oxide semiconductor layer while reducing defects in the insulating layer that cause the variation in characteristics of the semiconductor device.

Further, it is well-known that a semiconductor device with high mobility can be obtained by relatively increasing a ratio of indium contained in the oxide semiconductor layer. However, when the ratio of indium contained in the oxide semiconductor layer is high, oxygen deficiencies are likely to be formed in the oxide semiconductor layer. Therefore, in order to realize high mobility while maintaining high reliability, it is necessary to devise a configuration of the insulating layer around the oxide semiconductor layer.

An embodiment of the present invention can provide a semiconductor device with high mobility by suppressing diffusion of impurities into an oxide semiconductor layer.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a semiconductor device” means a positional relationship in which the semiconductor device and the pixel electrode overlap in a plan view. In addition, a plan view refers to viewing from a direction perpendicular to a surface of the substrate.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where a includes other components.

In addition, the following embodiments can be combined with each other as long as there is no technical contradiction.

### First Embodiment

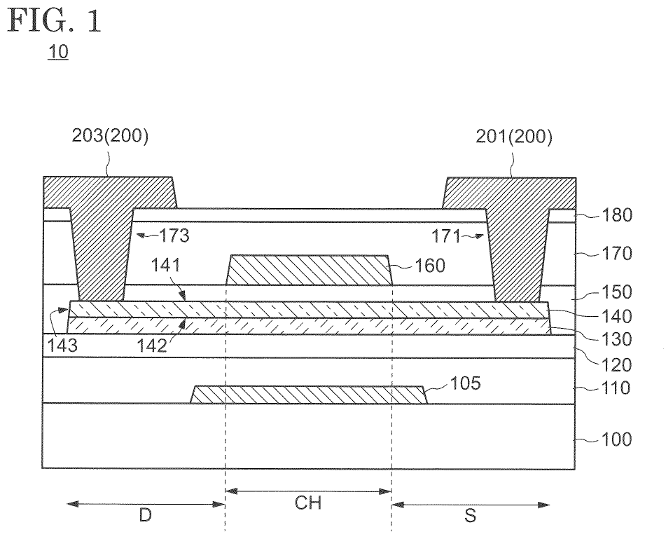

A semiconductor device 10 according to an embodiment of the present invention is described with reference to FIGS. 1 to 11. For example, the semiconductor device 10 of the embodiment described below may be used in an integrated circuit (IC) such as a micro-processing unit (MPU) or a memory circuit in addition to a transistor used in a display device.

### [Configuration of Semiconductor Device 10]

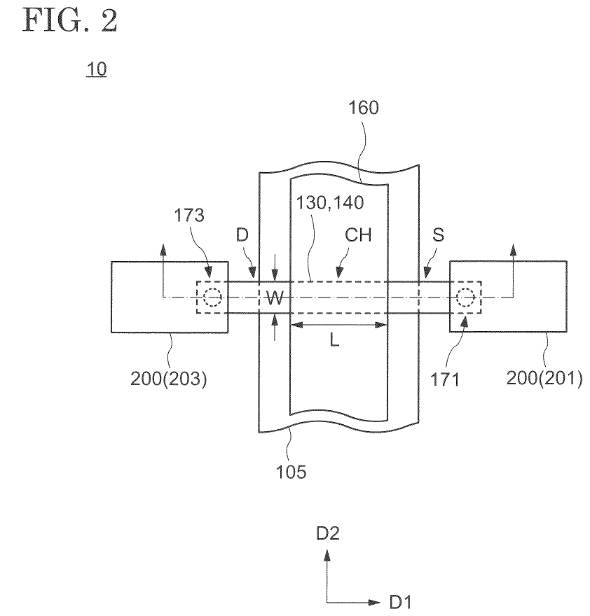

A configuration of the semiconductor device 10 according to an embodiment of the present invention is described with reference to FIGS. 1 and 2. FIG. 1 is a cross-sectional view showing an overview of the semiconductor device 10 according to an embodiment of the present invention. FIG. 2 is a plan view showing an overview of the semiconductor device 10 according to an embodiment of the present invention.

As shown in FIG. 1, the semiconductor device 10 is arranged over a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. When the source electrode 201 and the drain electrode 203 are not particularly distinguished from each other, they may be referred to as a source-drain electrode 200.

The gate electrode 105 is provided over the substrate 100. The gate insulating layer 110 and the gate insulating layer 120 are provided over the substrate 100 and the gate electrode 105. The metal oxide layer 130 is provided over the gate insulating layer 120. The metal oxide layer 130 is in contact with the gate insulating layer 120. The oxide semiconductor layer 140 is provided over the metal oxide layer 130. The oxide semiconductor layer 140 is in contact with the metal oxide layer 130. In main surfaces of the oxide semiconductor layer 140, a surface in contact with the metal oxide layer 130 is referred to as a lower surface 142. An end portion of the metal oxide layer 130 is substantially aligned with an end portion of the oxide semiconductor layer 140.

In the present embodiment, no semiconductor layer or oxide semiconductor layer is provided between the metal oxide layer 130 and the substrate 100.

In the present embodiment, although a configuration in which the metal oxide layer 130 is in contact with the gate insulating layer 120 and the oxide semiconductor layer 140 is in contact with the metal oxide layer 130 is exemplified, the configuration is not limited thereto. Other layers may be provided between the gate insulating layer 120 and the metal oxide layer 130. Other layers may be provided between the metal oxide layer 130 and the oxide semiconductor layer 140.

In FIG. 1, although a sidewall of the metal oxide layer 130 and a sidewall of the oxide semiconductor layer 140 are arranged in a straight line, the configuration is not limited thereto. An angle of the sidewall of the metal oxide layer 130 with respect to the main surface of the substrate 100 may be different from an angle of the sidewall of the oxide semiconductor layer 140 with respect to the main surface. The cross-sectional shape of the side wall of at least one of the metal oxide layer 130 and the oxide semiconductor layer 140 may be curved.

The gate electrode 160 faces the oxide semiconductor layer 140. The gate insulating layer 150 is provided between the oxide semiconductor layer 140 and the gate electrode 160. The gate insulating layer 150 is in contact with the oxide semiconductor layer 140. In the main surfaces of the oxide semiconductor layer 140, a surface in contact with the gate insulating layer 150 is referred to as an upper surface 141. A surface between the upper surface 141 and the lower surface 142 is referred to as a side surface 143. The insulating layers 170 and 180 are provided over the gate insulating layer 150 and the gate electrode 160. Openings 171 and 173 that reach the oxide semiconductor layer 140 are provided in the insulating layers 170 and 180. The source electrode 201 is provided inside the opening 171. The source electrode 201 is in contact with the oxide semiconductor layer 140 at the bottom of the opening 171. The drain electrode 203 is provided inside the opening 173. The drain electrode 203 is in contact with the oxide semiconductor layer 140 at the bottom of the opening 173.

The gate electrode 105 has a function as a bottom-gate of the semiconductor device 10 and a function as a light-shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom-gate. The metal oxide layer 130 is a layer that contains a metal oxide containing aluminum as the main component, and has a function as a gas barrier film for shielding a gas such as oxygen or hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and is closer to the drain electrode 203 than the channel region CH. The channel region CH in the oxide semiconductor layer 140 has physical properties of a semiconductor. The source region S and the drain region D in the oxide semiconductor layer 140 have physical properties of a conductor.

The gate electrode 160 has a function as a top-gate of the semiconductor device 10 and a light-shielding film for the oxide semiconductor layer 140. The gate insulating layer 150 has a function as a gate insulating layer for the top-gate, and has a function of releasing oxygen by a heat treatment in a manufacturing process. The insulating layers 170 and 180 insulate the gate electrode 160 and the source-drain electrode 200 and have a function of reducing parasitic capacitance therebetween. Operations of the semiconductor device 10 are controlled mainly by a voltage supplied to the gate electrode 160. An auxiliary voltage is supplied to the gate electrode 105. However, in the case of using the gate electrode 105 simply as a light-shielding film, a specific voltage is not supplied to the gate electrode 105, and the gate electrode 105 may be in a floating state. That is, the gate electrode 105 may simply be referred to as a “light-shielding film.”

In the present embodiment, although a configuration using a dual-gate transistor in which the gate electrode is provided both over and below the oxide semiconductor layer as the semiconductor device 10 is exemplified, the configuration is not limited thereto. For example, a bottom-gate transistor in which the gate electrode is provided only below the oxide semiconductor layer or a top-gate transistor in which the gate electrode is provided only over the oxide semiconductor layer may be used as the semiconductor device 10. The above configuration is merely one embodiment, and the present invention is not limited to the above configuration.

As shown in FIG. 2, in a plan view, a planar pattern of the metal oxide layer 130 is substantially the same as a planar pattern of the oxide semiconductor layer 140. Referring to FIGS. 1 and 2, the lower surface 142 of the oxide semiconductor layer 140 is covered with the metal oxide layer 130. In particular, in the present embodiment, the whole of the lower surface 142 of the oxide semiconductor layer 140 is covered with the metal oxide layer 130. In a direction D1, a width of the gate electrode 105 is greater than a width of the gate electrode 160. The direction D1 is a direction connecting the source electrode 201 and the drain electrode 203, and is a direction indicating a channel length L of the semiconductor device 10. Specifically, a length in the direction D1 in the region (the channel region CH) where the oxide semiconductor layer 140 and the gate electrode 160 overlap each other is the channel length L, and a width in a direction D2 in the channel region CH is a channel width W.

In the present embodiment, although a configuration in which all of the lower surface 142 of the oxide semiconductor layer 140 is covered with the metal oxide layer 130 is exemplified, the present invention is not limited thereto. For example, a part of the lower surface 142 of the oxide semiconductor layer 140 may not be in contact with the metal oxide layer 130. For example, the whole of the lower surface 142 of the channel region CH in the oxide semiconductor layer 140 may be covered with the metal oxide layer 130, and the whole or parts of the lower surface 142 of the source region S and the drain region D in the oxide semiconductor layer 140 may not be covered with the metal oxide layer 130. That is, the whole or parts of the lower surface 142 of the source region S and the drain region D in the oxide semiconductor layer 140 may not be in contact with the metal oxide layer 130. However, in the above configuration, a part of the lower surface 142 of the channel region CH in the oxide semiconductor layer 140 may not be covered with the metal oxide layer 130, and the other part of the lower surface 142 may be in contact with the metal oxide layer 130.

In the present embodiment, although the configuration in which the gate insulating layer 150 is formed on the entire surface and the openings 171 and 173 are provided in the gate insulating layer 150 is exemplified, the configuration is not limited thereto. The gate insulating layer 150 may be patterned. For example, the gate insulating layer 150 may be patterned to expose the whole or part of the source region S and the drain region D of the oxide semiconductor layer 140. That is, the gate insulating layer 150 on the source region S and the drain region D may be removed, and the source region S and the drain region D and the insulating layer 170 may be in contact with each other.

In FIG. 2, although the configuration in which the source-drain electrode 200 does not overlap the gate electrode 105 and the gate electrode 160 in a plan view is exemplified, the configuration is not limited thereto. For example, in a plan view, the source-drain electrode 200 may overlap at least one of the gate electrode 105 and the gate electrode 160. The above configuration is merely one embodiment, and the present invention is not limited to the above configuration.

### [Material of Each Member of Semiconductor Device 10]

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that reduce the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the gate electrode 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used for the gate electrode 105, the gate electrode 160, and the source-drain electrode 200. The above-described materials may be used in a single layer or in a stacked layer for the gate electrode 105, the gate electrode 160, and the source-drain electrode 200.

Common insulating materials are used for the gate insulating layers 110 and 120 and the insulating layers 170 and 180. For example, inorganic insulating materials such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) are used for the gate insulating layers 110 and 120 and the insulating layers 170 and 180.

Among the above-described inorganic insulating materials, the inorganic insulating material containing oxygen is used as the gate insulating layer 150. For example, an inorganic insulating material such as silicon oxide (SiOₓ), silicon oxynitride (SiOₓN_{y}), aluminum oxide (AlOₓ), aluminum oxynitride (AlOₓN_{y}), or the like is used for the gate insulating layer 150.

An insulating layer having a function of releasing oxygen by a heat treatment is used as the gate insulating layer 120. For example, the temperature of the heat treatment at which the gate insulating layer 120 releases oxygen is less than or equal to 600° C., less than or equal to 500° C., less than or equal to 450° C., or less than or equal to 400° C. That is, for example, in the case where the glass substrate is used as the substrate 100, the gate insulating layer 120 releases oxygen at the heat treatment temperature performed in the manufacturing process of the semiconductor device 10.

An insulating layer with few defects is used as the gate insulating layer 150. For example, when a composition ratio of oxygen in the gate insulating layer 150 is compared with a composition ratio of oxygen in an insulating layer (hereinafter referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by the electron-spin resonance (ESR) may be used as the gate insulating layer 150.

Silicon oxynitride (SiOₓN_{y}) and aluminum oxynitride (AlOₓN_{y}) are a silicon compound and an aluminum compound containing nitrogen (N) in a ratio (x>y) smaller than that of oxygen (O). Silicon nitride oxide (SiNₓO_{y}) and aluminum nitride oxide (AlNₓO_{y}) are a silicon compound and an aluminum compound containing oxygen (O) in a ratio (x>y) smaller than that of nitrogen (N).

A metal oxide containing aluminum as the main component is used for the metal oxide layer 130. For example, an inorganic insulating material such as aluminum oxide (AlOₓ), aluminum oxynitride (AlOₓN_{y}), or the like is used for the metal oxide layer 130. The “metal oxide layer containing aluminum as the main component” means that the ratio of aluminum contained in the metal oxide layer 130 is greater than or equal to 1% of the total amount of the metal oxide layer 130. The ratio of aluminum contained in the metal oxide layer 130 may be greater than or equal to 5% and less than or equal to 70%, greater than or equal to 10% and less than or equal to 60%, or greater than or equal to 30% and less than or equal to 50% of the total amount of the metal oxide layer 130. The above ratio may be a mass ratio or a weight ratio.

A metal oxide having semiconductor properties is used for the oxide semiconductor layer 140. For example, an oxide semiconductor containing two or more metal elements including indium (In) is used for the oxide semiconductor layer 140. In the oxide semiconductor layer 140, the ratio of indium to two or more metal elements is greater than or equal to 50%. Gallium (Ga), zinc (Zn), aluminum (Al), hafnium (Hf), yttrium (Y), zirconia (Zr), and lanthanoids are used as a metal element of the oxide semiconductor layer 140 in addition to indium. Metal elements other than those described above may be used for the oxide semiconductor layer 140.

The oxide semiconductor layer 140 may be amorphous or crystalline. The oxide semiconductor layer 140 may be a mixed phase of amorphous and crystalline. Oxygen deficiencies are likely to be formed in the oxide semiconductor layer 140 in which the ratio of indium is greater than or equal to 50%, as described below. Oxygen deficiencies are less likely to be formed in a crystalline oxide semiconductor as compared with an amorphous oxide semiconductor. Therefore, it is preferable that the oxide semiconductor layer 140 is crystalline.

### [Problems Newly Recognized in Process of Reaching Present Invention]

In the case where the ratio of indium in the oxide semiconductor layer 140 is greater than or equal to 50%, the semiconductor device 10 with high mobility is realized. On the other hand, since the oxygen contained in the oxide semiconductor layer 140 is easily reduced in such an oxide semiconductor layer 140, oxygen deficiencies are easily formed in the oxide semiconductor layer 140.

In the semiconductor device 10, hydrogen is released from a layer (for example, the gate insulating layers 110 and 120) provided closer to the substrate 100 than the oxide semiconductor layer 140 in the heat treatment step of the manufacturing process. When hydrogen reaches the oxide semiconductor layer 140, oxygen deficiencies occur in the oxide semiconductor layer 140. The occurrence of the oxygen deficiencies is more pronounced as the pattern size of the oxide semiconductor layer 140 becomes larger. In order to suppress the occurrence of such oxygen deficiencies, it is necessary to suppress hydrogen from reaching the lower surface 142 of the oxide semiconductor layer 140. This is the first problem.

Apart from the above problem, there is the second problem shown below. The upper surface 141 of the oxide semiconductor layer 140 is affected by a process (for example, a patterning process or an etching process) after the oxide semiconductor layer 140 is formed. On the other hand, the lower surface 142 of the oxide semiconductor layer 140 (the surface of the oxide semiconductor layer 140 facing the substrate 100) is not affected as described above.

Therefore, there are more oxygen deficiencies formed close to the upper surface 141 of the oxide semiconductor layer 140 than the oxygen deficiencies formed close to the lower surface 142 of the oxide semiconductor layer 140. That is, the oxygen deficiencies in the oxide semiconductor layer 140 do not exist uniformly in a thickness direction of the oxide semiconductor layer 140, but exist in a non-uniform distribution in the thickness direction of the oxide semiconductor layer 140. Specifically, there are fewer oxygen deficiencies in the oxide semiconductor layer 140 on the side of the lower surface 142 of the oxide semiconductor layer 140 and more oxygen deficiencies on the side of the upper surface 141 of the oxide semiconductor layer 140.

In the case where an oxygen supplying treatment is uniformly performed on the oxide semiconductor layer 140 having the oxygen deficiency distribution as described above, oxygen is excessively supplied to the lower surface 142 of the oxide semiconductor layer 140 when supplying oxygen in an amount required to repair the oxygen deficiencies formed on the upper surface 141 of the oxide semiconductor layer 140. As a result, a defect level different from the oxygen deficiencies is formed on the lower surface 142 due to the excess oxygen. As a result, phenomenon such as variation in characteristics in the reliability test or a decrease in field-effect mobility occurs. Therefore, in order to suppress such phenomenon, it is necessary to supply oxygen to the upper surface 141 of the oxide semiconductor layer 140 while suppressing the oxygen supply to the lower surface 142 of the oxide semiconductor layer 140.

The above problems are newly recognized in the process of reaching the present invention but are not problems that have been conventionally recognized. In the conventional configuration and manufacturing method, there was a trade-off relationship between the initial characteristics and the reliability test, in which the variation in characteristics according to the reliability test occurs even when the initial characteristics of the semiconductor device are improved by the oxygen supply process to the oxide semiconductor layer. However, with the configuration according to the present embodiment, the above problems are solved, and it is possible to obtain good initial characteristics and a reliability test of the semiconductor device 10.

### [Manufacturing Method of Semiconductor Device 10]

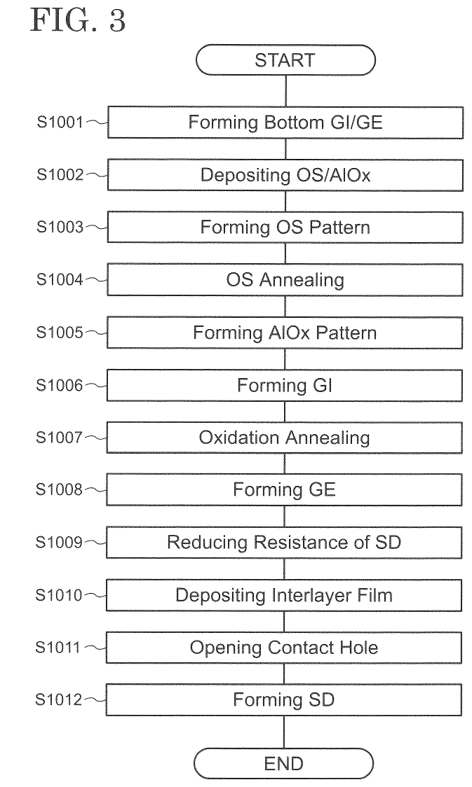

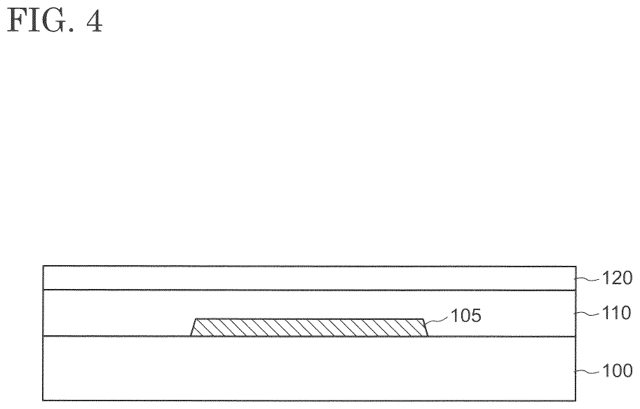

A method for manufacturing the semiconductor device 10 according to an embodiment of the present invention will be described with reference to FIGS. 3 to 11. FIG. 3 is a sequence diagram showing the method for manufacturing the semiconductor device 10 according to an embodiment of the present invention. FIGS. 4 to 11 are cross-sectional views showing the method for manufacturing the semiconductor device 10 according to an embodiment of the present invention. In the following description, the method for manufacturing the semiconductor device 10 in which aluminum oxide is used for the metal oxide layers 130 is described.

As shown in FIGS. 3 and 4, the gate electrode 105 is formed on the substrate 100 as the bottom-gate, and the gate insulating layers 110 and 120 are formed on the gate electrode 105 (“Forming Bottom GI/GE” in step S1001 of FIG. 3). For example, silicon nitride is formed for the gate insulating layer 110. For example, silicon oxide is formed for the gate insulating layer 120. The gate insulating layers 110 and 120 are deposited by a CVD (Chemical Vapor Deposition) method.

When silicon nitride is used for the gate insulating layer 110, the gate insulating layer 110 can block impurities that diffuse, for example, from the substrate 100 toward the oxide semiconductor layer 140. The silicon oxide used for the gate insulating layer 120 is silicon oxide having a physical property of releasing oxygen by a heat treatment.

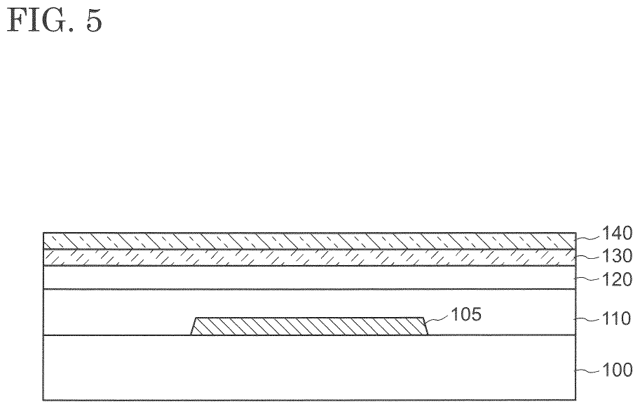

As shown in FIGS. 3 and 5, the metal oxide layer 130 and the oxide semiconductor layer 140 are deposited on the gate insulating layer 120 (“Depositing OS/AlOₓ” in step S1002 of FIG. 3). The metal oxide layer 130 and the oxide semiconductor layer 140 are deposited by a sputtering method or an atomic layer deposition (ALD) method.

For example, a thickness of the metal oxide layer 130 is greater than or equal to 1 nm and less than or equal to 100 nm, greater than or equal to 1 nm and less than or equal to 50 nm, greater than or equal to 1 nm and less than or equal to 30 nm, or greater than or equal to 1 nm and less than or equal to 10 nm. In the present embodiment, aluminum oxide is used for the metal oxide layer 130. Aluminum oxide has a high barrier property against gas. In the present embodiment, aluminum oxide used for the metal oxide layer 130 blocks hydrogen, nitrogen, and oxygen released from the gate insulating layer 120, and suppresses the released hydrogen, nitrogen, and oxygen from reaching the oxide semiconductor layer 140.

As described above, the metal oxide layer 130 can block hydrogen and nitrogen. Therefore, a hydrogen concentration in a region (a first region) of the gate insulating layer 120 overlapping the metal oxide layer is higher than a hydrogen concentration in a region (a second region) of the gate insulating layer 120 not overlapping the metal oxide layer. Similarly, a nitrogen concentration in the first region is higher than a nitrogen concentration in the second region. Further, the nitrogen concentration in the first region increases from the substrate 100 toward the metal oxide layer 130.

For example, a thickness of the oxide semiconductor layer 140 is greater than or equal to 10 nm and less than or equal to 100 nm, greater than or equal to 15 nm and less than or equal to 70 nm, or greater than or equal to 20 nm and less than or equal to 40 nm. In the present embodiment, an oxide containing indium (In) and gallium (Ga), and aluminum as an impurity is used for the oxide semiconductor layer 140. The oxide semiconductor layer 140 before the heat treatment (OS annealing) described later is amorphous.

When the oxide semiconductor layer 140 is crystallized by the OS annealing described later, it is preferable that the oxide semiconductor layer 140 after the deposition and before the OS annealing is in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by a sputtering method, ions generated in the plasma and atoms recoiled by a sputtering target collide with the object to be deposited. Thus, the temperature of the object to be deposited rises with the deposition process. When the temperature of the object to be deposited rises during the deposition process, microcrystals are included in the oxide semiconductor layer 140 immediately after the deposition process. The microcrystals inhibit crystallization by a subsequent OS annealing. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is less than or equal to 100° C., less than or equal to 70° C., less than or equal to 50° C., or less than or equal to 30° C. As described above, when the oxide semiconductor layer 140 is deposited while cooling the object to be deposited, it is possible to deposit the oxide semiconductor layer 140 with few crystalline components in a state immediately after the deposition.

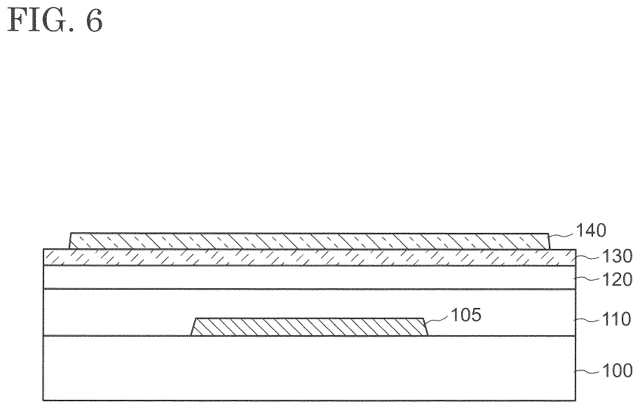

As shown in FIGS. 3 and 6, a pattern of the oxide semiconductor layer 140 is formed (“Forming OS Pattern” in step S1003 of FIG. 3). Although not shown in the figures, a resist mask is formed on the oxide semiconductor layer 140, and the oxide semiconductor layer 140 is etched using the resist mask. Wet etching or dry etching may be used for the etching method of the oxide semiconductor layer 140. The wet etching may be performed using an acidic etchant. For example, oxalic acid or hydrofluoric acid may be used as the etchant.

A heat treatment (“OS Annealing” in step S1004 of FIG. 3) is performed on the oxide semiconductor layer 140 after the pattern of the oxide semiconductor layer 140 is formed. In the present embodiment, the oxide semiconductor layer 140 is crystallized by the OS annealing. Further, in the present embodiment, since impurities such as hydrogen and nitrogen contained in the oxide semiconductor layer 140 are reduced, the crystallinity of the oxide semiconductor layer 140 is improved. Furthermore, since impurities such as hydrogen and nitrogen contained in the oxide semiconductor layer 140 are reduced by the metal oxide layer 130, the film quality of the oxide semiconductor layer 140 is improved. Therefore, the size dependency of the electrical characteristics of the semiconductor device 10 can be suppressed.

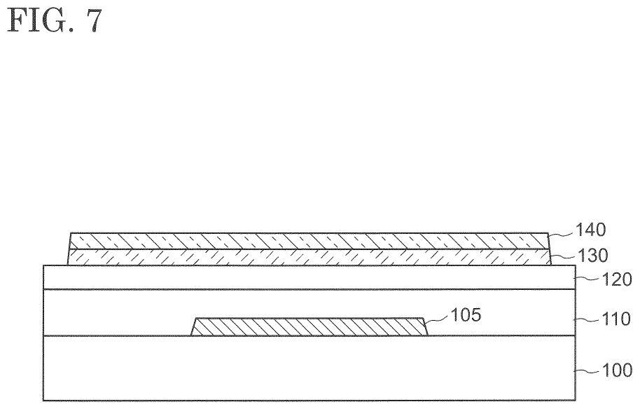

As shown in FIGS. 3 and 7, a pattern of the metal oxide layer 130 is formed (“Forming AlOₓ Pattern” in step S1005 of FIG. 3). The metal oxide layer 130 is etched using the oxide semiconductor layer 140 patterned in the above process as a mask. Wet etching or dry etching may be used for the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

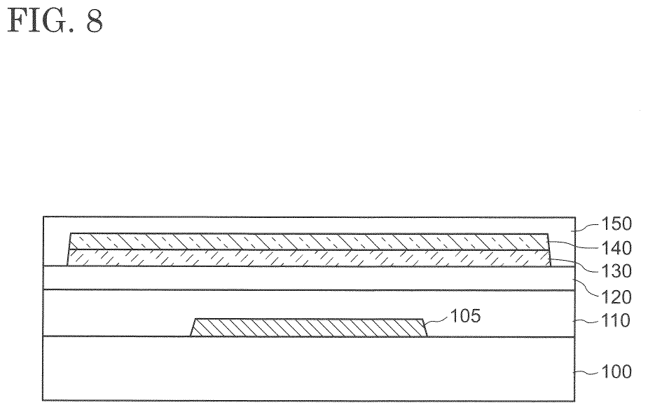

As shown in FIGS. 3 and 8, the gate insulating layer 150 is deposited on the oxide semiconductor layer 140 (“Forming GI” in step S1006 of FIG. 3). For example, silicon oxide is formed for the gate insulating layer 150. The gate insulating layer 150 is deposited by a CVD method. For example, the gate insulating layer 150 may be deposited at a deposition temperature higher than or equal to 350° C. in order to form an insulating layer having few defects as described above. For example, a thickness of the gate insulating layer 150 is greater than or equal to 50 nm and less than or equal to 300 nm, greater than or equal to 60 nm and less than or equal to 200 nm, or greater than or equal to 70 nm and less than or equal to 150 nm. A process of implanting oxygen may be performed on a part of the gate insulating layer 150 after the gate insulating layer 150 is deposited.

A heat treatment for supplying oxygen to the oxide semiconductor layer 140 is performed in a state where the gate insulating layer 150 is deposited on the oxide semiconductor layer 140 (“Oxidation Annealing” in step S1007 of FIG. 3). In the process from the deposition of the oxide semiconductor layer 140 to the deposition of the gate insulating layer 150 on the oxide semiconductor layer 140, a large amount of oxygen deficiencies is formed in the upper surface 141 and the side surface 143 of the oxide semiconductor layer 140. Oxygen released from the gate insulating layers 120 and 150 is supplied to the oxide semiconductor layer 140 by the above-described oxidation annealing, and the oxygen deficiencies are repaired.

Oxygen released from the gate insulating layer 120 by the oxidation annealing is blocked by the metal oxide layer 130. Therefore, oxygen is less likely to be supplied to the lower surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 through the gate insulating layer 150. As a result, the oxygen released from the gate insulating layer 120 is less likely to be supplied to the lower surface 142 of the oxide semiconductor layer 140, and is mainly supplied to the side surface 143 and the upper surface 141 of the oxide semiconductor layer 140. Further, the oxidation annealing makes it possible to supply oxygen released from the gate insulating layer 150 to the upper surface 141 and the side surface 143 of the oxide semiconductor layer 140. Although the oxidation annealing may release hydrogen and nitrogen from the gate insulating layers 110 and 120, the released hydrogen and nitrogen are blocked by the metal oxide layer 130.

As described above, in the oxidation annealing, it is possible to supply oxygen to the upper surface 141 and the side surface 143 of the oxide semiconductor layer 140 having a large amount of oxygen deficiencies while suppressing the supply of oxygen to the lower surface 142 of the oxide semiconductor layer 140 having a small amount of oxygen deficiencies.

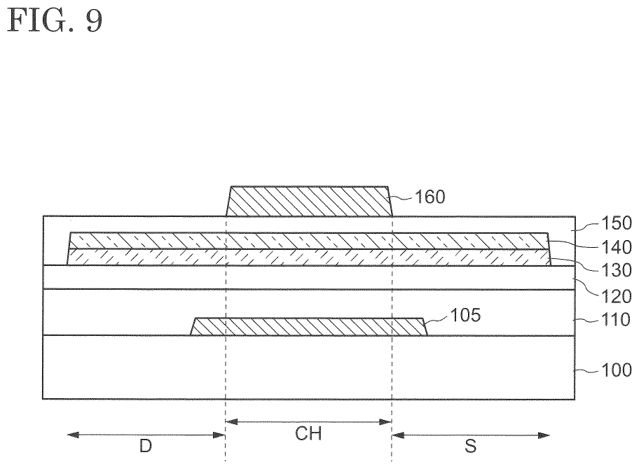

As shown in FIGS. 3 and 9, the gate electrode 160 is formed on the gate insulating layer 150 (“Forming GE” in step S1008 of FIG. 3). The gate electrode 160 is deposited by a sputtering method or an atomic layer deposition method and patterned by a photolithography process.

Resistances of the source region S and the drain region D of the oxide semiconductor layer 140 are reduced (“Reducing resistance of SD” in step S1009 of FIG. 3) in a state where the gate electrode 160 is patterned. Specifically, impurities are implanted into the oxide semiconductor layer 140 from the gate electrode 160 side through the gate insulating layer 150 by ion implantation. For example, argon (Ar), phosphorus (P), and boron (B) are implanted into the oxide semiconductor layer 140 by the ion implantation. When oxygen deficiencies are formed in the oxide semiconductor layer 140 by the ion implantation, the resistance of the oxide semiconductor layer 140 is reduced. Since the channel region CH in the semiconductor device 140 is provided so as to overlap the gate electrode 160 in the semiconductor device 10, impurities are not implanted into the channel region CH in the oxide semiconductor layer 140.

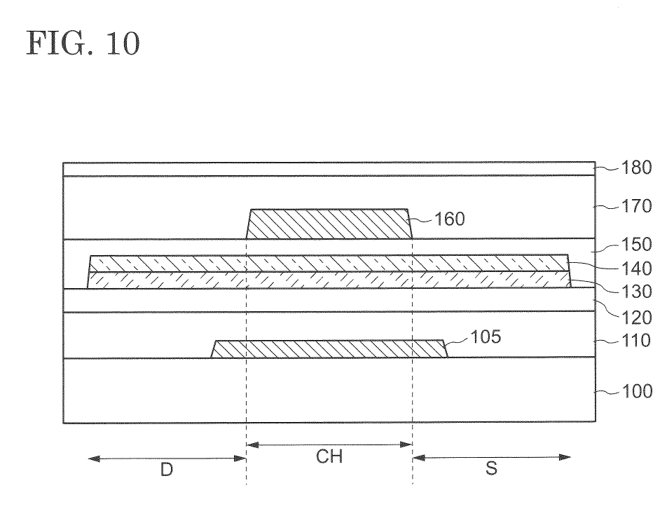

As shown in FIGS. 3 and 10, the insulating layers 170 and 180 are deposited on the gate insulating layer 150 and the gate electrode 160 as interlayer films (“Depositing Interlayer Film” in step S1010 of FIG. 3). The insulating layers 170 and 180 are deposited by a CVD method. For example, silicon nitride is deposited for the insulating layer 170, and silicon oxide is deposited for the insulating layer 180. The materials used for the insulating layers 170 and 180 are not limited thereto. A thickness of the insulating layer 170 is greater than or equal to 50 nm and less than or equal to 500 nm. A thickness of the insulating layer 180 is greater than or equal to 50 nm and less than or equal to 500 nm.

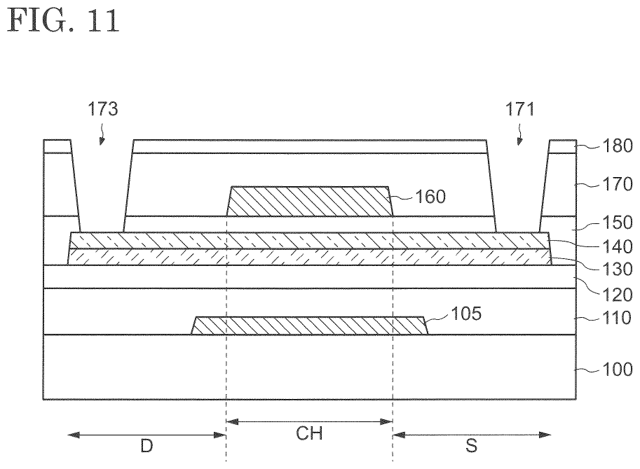

As shown in FIGS. 3 and 11, the openings 171 and 173 are formed in the gate insulating layer 150 and the insulating layers 170 and 180 (“Opening Contact Hole” in step S2013 of FIG. 3). The oxide semiconductor layer 140 in the source region S is exposed by the opening 171. The oxide semiconductor layer 140 in the drain region D is exposed by the opening 173. The semiconductor device 10 shown in FIG. 1 is completed by forming the source-drain electrode 200 on the insulating layer 180 so as to be in contact with the oxide semiconductor layer 140 exposed by the openings 171 and 173 (“Forming SD” in step S1012 of FIG. 3).

With respect to the semiconductor device 10 manufactured by the above-described manufacturing method, it is possible to obtain electrical characteristics having a mobility greater than or equal to 30 cm²/Vs, greater than or equal to 35 cm²/Vs, or greater than or equal to 40 cm²/Vs in a range where the channel length L of the channel region CH is greater than or equal to 2 μm and less than or equal to 4 μm and the channel width of the channel region CH is greater than or equal to 2 μm and less than or equal to 25 μm. The mobility in the present embodiment is the field-effect mobility in a saturation region in the electrical characteristics of the semiconductor device 10. Specifically, the mobility means the maximum value of the field-effect mobility in a region where a potential difference (Vd) between the source electrode and the drain electrode is greater than a value (Vg−Vth) obtained by subtracting a threshold-voltage (Vth) of the semiconductor device 10 from a voltage (Vg) supplied to the gate electrode.

Further, in the semiconductor device 10 manufactured by the above manufacturing method, so-called normally-off (enhancement type) electrical characteristics can be obtained in a range where the channel length L of the channel region CH is greater than or equal to 2 μm and less than or equal to 4 μm and the channel width of the channel region CH is greater than or equal to 2 μm and less than or equal to 25 μm.

### Second Embodiment

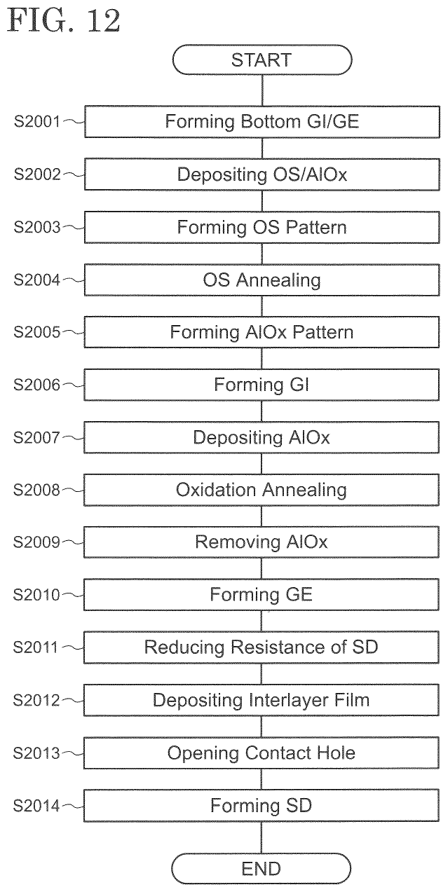

A semiconductor device 10 according to an embodiment of the present invention is described with reference to FIGS. 12 to 21. For example, the semiconductor device 10 of the embodiment described below may be used in an integrated circuit (IC) such as a micro-processing unit (MPU) or a memory circuit in addition to a transistor used in a display device.

### [Configuration of Semiconductor Device 10]

A configuration of the semiconductor device 10 according to the present embodiment is similar to the configuration of the semiconductor device 10 described in the First Embodiment. Therefore, the semiconductor device 10 according to the present embodiment is described with reference to FIGS. 1 and 2. However, the semiconductor device 10 according to the present embodiment differs from the semiconductor device 10 according to the First Embodiment in the manufacturing method. Therefore, in the present embodiment, the description of the configuration of the semiconductor device 10 is omitted, and the manufacturing method is described. In the following description, the same material as the metal oxide layer 130 is used for the metal oxide layer 190.

### [Manufacturing Method of Semiconductor Device 10]

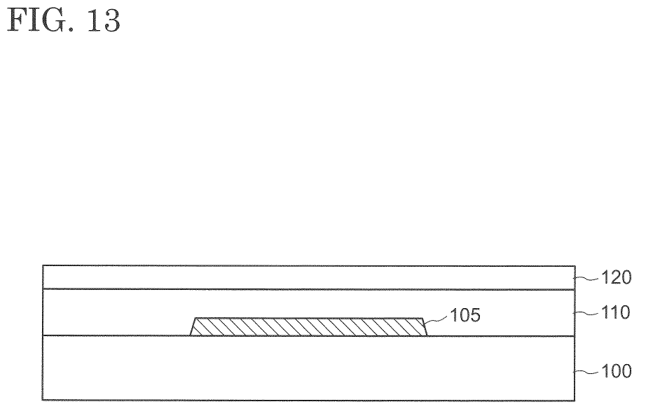

A method for manufacturing the semiconductor device 10 according to an embodiment of the present invention will be described with reference to FIGS. 12 to 21. FIG. 12 is a sequence diagram showing the method for manufacturing the semiconductor device 10 according to an embodiment of the present invention. FIGS. 13 to 21 are cross-sectional views showing the method for manufacturing the semiconductor device 10 according to an embodiment of the present invention. In the following description, the method for manufacturing the semiconductor device 10 in which aluminum oxide is used for the metal oxide layers 130 and 190 is described.

As shown in FIGS. 12 and 13, the gate electrode 105 is formed on the substrate 100 as the bottom-gate, and the gate insulating layers 110 and 120 are formed on the gate electrode 105 (“Forming Bottom GI/GE” in step S2001 of FIG. 12). For example, silicon nitride is formed for the gate insulating layer 110. For example, silicon oxide is formed for the gate insulating layer 120. The gate insulating layers 110 and 120 are deposited by a CVD (Chemical Vapor Deposition) method.

When silicon nitride is used for the gate insulating layer 110, the gate insulating layer 110 can block impurities that diffuse, for example, from the substrate 100 toward the oxide semiconductor layer 140. The silicon oxide used for the gate insulating layer 120 is silicon oxide having a physical property of releasing oxygen by a heat treatment.

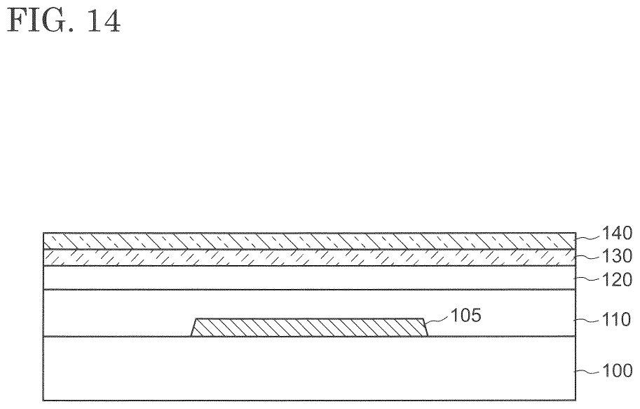

As shown in FIGS. 12 and 14, the metal oxide layer 130 and the oxide semiconductor layer 140 are deposited on the gate insulating layer 120 (“Depositing OS/AlOₓ” in step S2002 of FIG. 12). The metal oxide layer 130 and the oxide semiconductor layer 140 are deposited by a sputtering method or an atomic layer deposition (ALD) method.

For example, a thickness of the metal oxide layer 130 is greater than or equal to 1 nm and less than or equal to 100 nm, greater than or equal to 1 nm and less than or equal to 50 nm, greater than or equal to 1 nm and less than or equal to 30 nm, or greater than or equal to 1 nm and less than or equal to 10 nm. In the present embodiment, aluminum oxide is used for the metal oxide layer 130. Aluminum oxide has a high barrier property against gas. In the present embodiment, aluminum oxide used for the metal oxide layer 130 blocks hydrogen, nitrogen, and oxygen released from the gate insulating layer 120, and suppresses the released hydrogen, nitrogen, and oxygen from reaching the oxide semiconductor layer 140.

As described above, the metal oxide layer 130 can block hydrogen and nitrogen. Therefore, the hydrogen concentration in the region (the first region) of the gate insulating layer 120 overlapping the metal oxide layer is higher than the hydrogen concentration in the region (the second region) of the gate insulating layer 120 not overlapping the metal oxide layer. Similarly, the nitrogen concentration in the first region is higher than the nitrogen concentration in the second region. Further, the nitrogen concentration in the first region increases from the substrate 100 toward the metal oxide layer 130.

For example, a thickness of the oxide semiconductor layer 140 is greater than or equal to 10 nm and less than or equal to 100 nm, greater than or equal to 15 nm and less than or equal to 70 nm, or greater than or equal to 20 nm and less than or equal to 40 nm. In the present embodiment, an oxide containing indium (In) and gallium (Ga), and aluminum (Al) as an impurity (additive) is used for the oxide semiconductor layer 140. The oxide semiconductor layer 140 before the OS annealing described later is amorphous.

When the oxide semiconductor layer 140 is crystallized by the OS annealing described later, it is preferable that the oxide semiconductor layer 140 after the deposition and before the OS annealing is in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by a sputtering method, ions generated in the plasma and atoms recoiled by a sputtering target collide with the object to be deposited. Thus, the temperature of the object to be deposited rises with the deposition process. When the temperature of the object to be deposited rises during the deposition process, microcrystals are included in the oxide semiconductor layer 140 immediately after the deposition process. The microcrystals inhibit crystallization by a subsequent OS annealing. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited is less than or equal to 100° C., less than or equal to 70° C., less than or equal to 50° C., or less than or equal to 30° C. As described above, when the oxide semiconductor layer 140 is deposited while cooling the object to be deposited, it is possible to deposit the oxide semiconductor layer 140 with few crystalline components in a state immediately after the deposition.

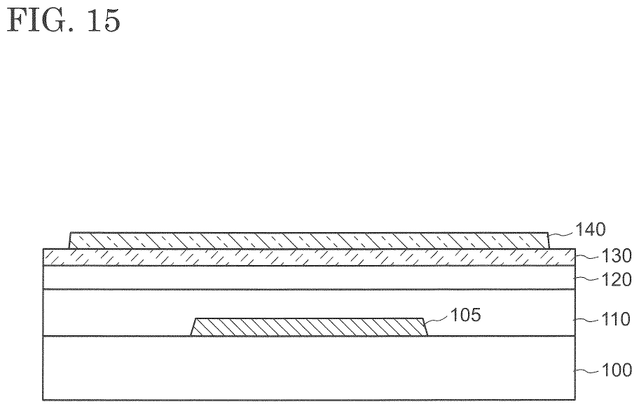

As shown in FIGS. 12 and 15, a pattern of the oxide semiconductor layer 140 is formed (“Forming OS Pattern” in step S2003 of FIG. 12). Although not shown in the figures, a resist mask is formed on the oxide semiconductor layer 140, and the oxide semiconductor layer 140 is etched using the resist mask. Wet etching or dry etching may be used for the etching method of the oxide semiconductor layer 140. The wet etching may be performed using an acidic etchant. For example, oxalic acid or hydrofluoric acid may be used as the etchant.

A heat treatment (“OS Annealing” in step S2004 of FIG. 12) is performed on the oxide semiconductor layer 140 after the pattern of the oxide semiconductor layer 140 is formed. In the present embodiment, the oxide semiconductor layer 140 is crystallized by the OS annealing. In the present embodiment, since impurities such as hydrogen and nitrogen contained in the oxide semiconductor layer 140 are reduced, the crystallinity of the oxide semiconductor layer 140 is improved. Furthermore, since impurities such as hydrogen and nitrogen contained in the oxide semiconductor layer 140 are reduced by the metal oxide layer 130, the film quality of the oxide semiconductor layer 140 is improved. Therefore, the size dependency of the electrical characteristics of the semiconductor device 10 can be suppressed.

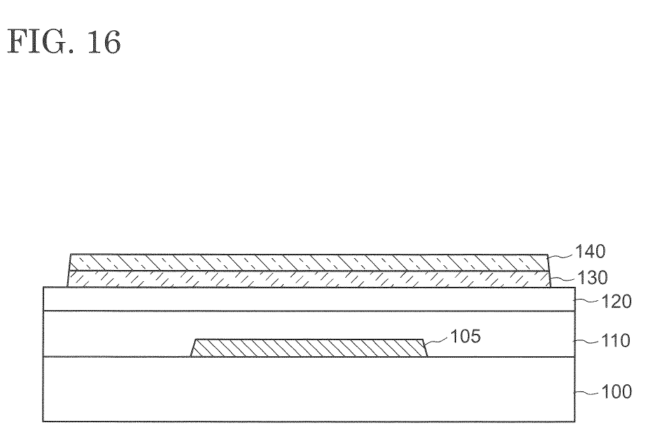

As shown in FIGS. 12 and 16, a pattern of the metal oxide layer 130 is formed (“Forming AlOₓ Pattern” in step S2005 of FIG. 12). The metal oxide layer 130 is etched using the oxide semiconductor layer 140 patterned in the above process as a mask. Wet etching or dry etching may be used for the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

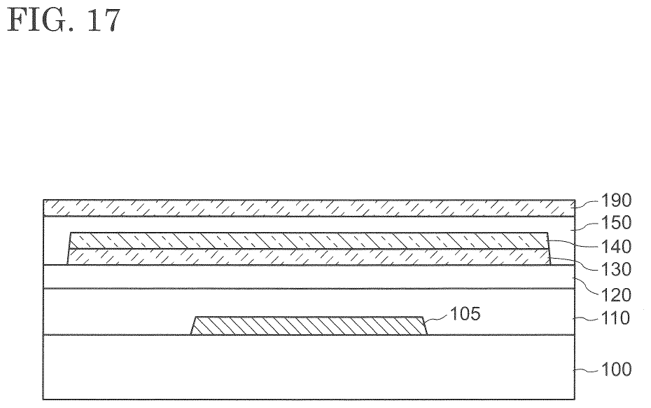

As shown in FIGS. 12 and 17, the gate insulating layer 150 is deposited on the oxide semiconductor layer 140 (“Forming GI” in step S2006 of FIG. 12). For example, silicon oxide is formed for the gate insulating layer 150. The gate insulating layer 150 is deposited by a CVD method. For example, the gate insulating layer 150 may be deposited at a deposition temperature higher than or equal to 350° C. in order to form an insulating layer having few defects as described above as the gate insulating layer 150. For example, a thickness of the gate insulating layer 150 is greater than or equal to 50 nm and less than or equal to 300 nm, greater than or equal to 60 nm and less than or equal to 200 nm, or greater than or equal to 70 nm and less than or equal to 150 nm. A process of implanting oxygen may be performed on a part of the gate insulating layer 150 after the gate insulating layer 150 is deposited. The metal oxide layer 190 is deposited on the gate insulating layer 150 (“Depositing AlOₓ” in step S2007 of FIG. 12). The metal oxide layer 190 is deposited by a sputtering method. Oxygen is implanted into the gate insulating layer 150 by the deposition of the metal oxide layer 190.

For example, a thickness of the metal oxide layer 190 is greater than or equal to 5 nm and less than or equal to 100 nm, greater than or equal to 5 nm and less than or equal to 50 nm, greater than or equal to 5 nm and less than or equal to 30 nm, or greater than or equal to 7 nm and less than or equal to 15 nm. In the present embodiment, aluminum oxide is used for the metal oxide layer 190. Aluminum oxide has a high barrier property against gas. In the present embodiment, aluminum oxide used for the metal oxide layer 190 suppresses the oxygen implanted into the gate insulating layer 150 at the time of the deposition of the metal oxide layer 190 from diffusing outward.

For example, in the case where the metal oxide layer 190 is deposited by a sputtering method, a process gas used in the sputtering method remains in the metal oxide layer 190. For example, in the case where Ar is used as the process gas for the sputtering method, Ar may remain in the metal oxide layer 190. The remaining Ar can be detected by a Secondary Ion Mass Spectrometry (SIMS) analysis on the metal oxide layer 190.

A heat treatment for supplying oxygen to the oxide semiconductor layer 140 is performed in a state where the gate insulating layer 150 is deposited on the oxide semiconductor layer 140 and the metal oxide layer 190 is deposited on the gate insulating layer 150 (“Oxidation Annealing” in step S2008 of FIG. 12). In the process from the deposition of the oxide semiconductor layer 140 to the deposition of the gate insulating layer 150 on the oxide semiconductor layer 140, a large amount of oxygen deficiencies is formed in the upper surface 141 and the side surface 143 of the oxide semiconductor layer 140. Oxygen released from the gate insulating layers 120 and 150 is supplied to the oxide semiconductor layer 140 by the above-described oxidation annealing, and the oxygen deficiencies are repaired.

Oxygen released from the gate insulating layer 120 by the oxidation annealing is blocked by the metal oxide layer 130. Therefore, oxygen is less likely to be supplied to the lower surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 through the gate insulating layer 150. As a result, the oxygen released from the gate insulating layer 120 is less likely to be supplied to the lower surface 142 of the oxide semiconductor layer 140, and is mainly supplied to the side surface 143 and the upper surface 141 of the oxide semiconductor layer 140. Further, the oxidation annealing makes it possible to supply oxygen released from the gate insulating layer 150 to the upper surface 141 and the side surface 143 of the oxide semiconductor layer 140. Although the oxidation annealing may release hydrogen and nitrogen from the gate insulating layers 110 and 120, the released hydrogen and nitrogen is blocked by the metal oxide layer 130.

As described above, in the oxidation annealing, it is possible to supply oxygen to the upper surface 141 and the side surface 143 of the oxide semiconductor layer 140 having a large amount of oxygen deficiencies while suppressing the supply of oxygen to the lower surface 142 of the oxide semiconductor layer 140 having a small amount of oxygen deficiencies.

Similarly, in the oxidation annealing described above, the oxygen implanted in the gate insulating layer 150 is blocked by the metal oxide layer 190. Therefore, the oxygen is suppressed from being released to the atmosphere. As a result, oxygen is efficiently supplied to the oxide semiconductor layer 140 by the oxidation annealing, and the oxygen deficiencies are repaired.

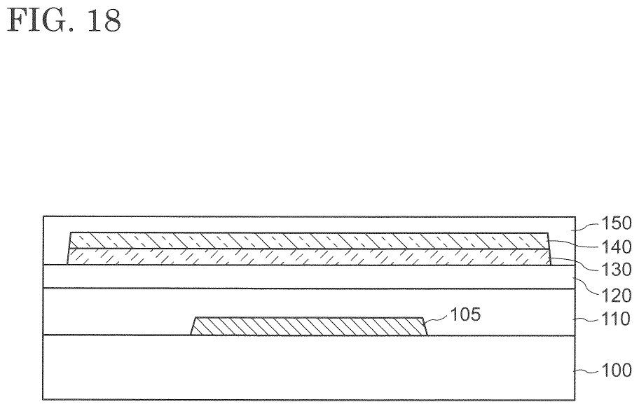

As shown in FIGS. 12 and 18, the metal oxide layer 190 is etched (removed) after the oxidation annealing (“Removing AlOₓ” in step S2009 of FIG. 12). Wet etching or dry etching may be used for the etching method of the metal oxide layer 190. For example, dilute hydrofluoric acid (DHF) is used for the wet etching.

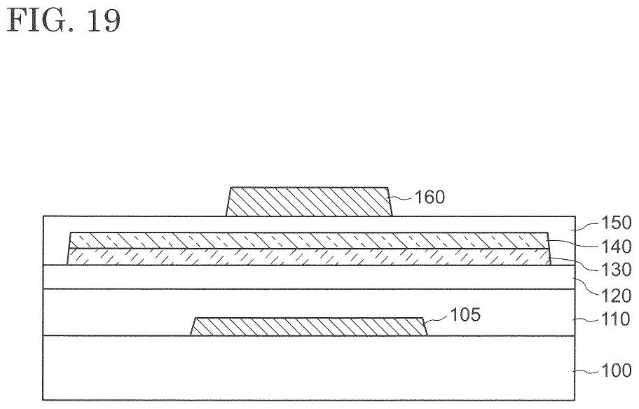

As shown in FIGS. 12 and 19, the gate electrode 160 is formed on the gate insulating layer 150 (“Forming GE” in step S2010 of FIG. 12). The gate electrode 160 is deposited by a sputtering method or an atomic layer deposition method and patterned by a photolithography process.

Resistances of the source region S and the drain region D of the oxide semiconductor layer 140 are reduced (“Reducing resistance of SD” in step S2011 of FIG. 12) in a state where the gate electrode 160 is patterned. Specifically, impurities are implanted into the oxide semiconductor layer 140 from the gate electrode 160 side through the gate insulating layer 150 by ion implantation. For example, argon (Ar), phosphorus (P), and boron (B) are implanted into the oxide semiconductor layer 140 by the ion implantation. When oxygen deficiencies are formed in the oxide semiconductor layer 140 by the ion implantation, the resistance of the oxide semiconductor layer 140 is reduced. Since the channel region CH in the semiconductor device 140 is provided so as to overlap the gate electrode 160 in the semiconductor device 10, impurities are not implanted into the channel region CH in the oxide semiconductor layer 140.

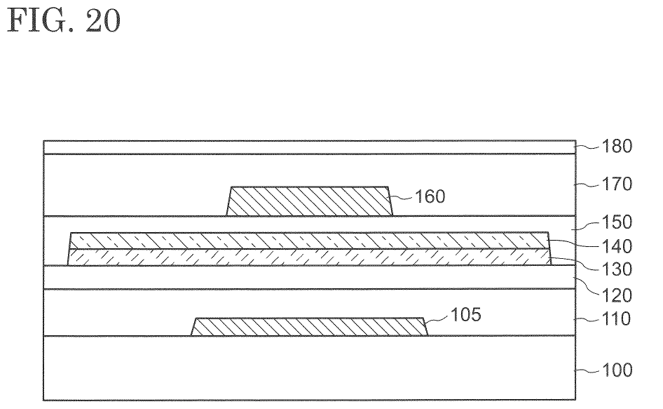

As shown in FIGS. 12 and 20, the insulating layers 170 and 180 are deposited on the gate insulating layer 150 and the gate electrode 160 as interlayer films (“Depositing Interlayer Film” in step S2012 of FIG. 12). The insulating layers 170 and 180 are deposited by a CVD method. For example, silicon nitride is deposited for the insulating layer 170, and silicon oxide is deposited for the insulating layer 180. The materials used for the insulating layers 170 and 180 are not limited thereto. A thickness of the insulating layer 170 is greater than or equal to 50 nm and less than or equal to 500 nm. A thickness of the insulating layer 180 is greater than or equal to 50 nm and less than or equal to 500 nm.

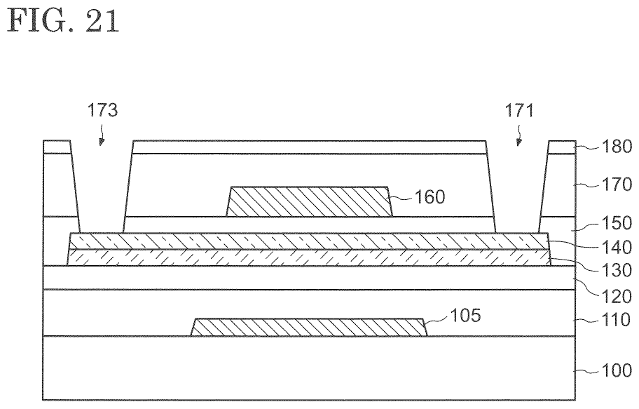

As shown in FIGS. 12 and 21, the openings 171 and 173 are formed in the gate insulating layer 150 and the insulating layers 170 and 180 (“Opening Contact Hole” in step S2013 of FIG. 12). The oxide semiconductor layer 140 in the source region S is exposed by the opening 171. The oxide semiconductor layer 140 in the drain region D is exposed by the opening 173. The semiconductor device 10 shown in FIG. 1 is completed by forming the source-drain electrode 200 on the insulating layer 180 so as to be in contact with the oxide semiconductor layer 140 exposed by the openings 171 and 173 (“Forming SD” in step S2014 of FIG. 12).

With respect to the semiconductor device 10 manufactured by the above-described manufacturing method, it is possible to obtain electrical characteristics having a mobility greater than or equal to 50 cm²/Vs, greater than or equal to 55 cm²/Vs, or greater than or equal to 60 cm²/Vs in a range where the channel length L of the channel region CH is greater than or equal to 2 μm and less than or equal to 4 μm and the channel width of the channel region CH is greater than or equal to 2 μm and less than or equal to 25 μm. The mobility in the present embodiment is the field-effect mobility in a saturation region in the electrical characteristics of the semiconductor device 10. Specifically, the mobility means the maximum value of the field-effect mobility in a region where a potential difference (Vd) between the source electrode and the drain electrode is greater than a value obtained by subtracting a threshold-voltage (Vth) of the semiconductor device 10 from a voltage (Vg) supplied to the gate electrode.

Further, in the semiconductor device 10 manufactured by the above manufacturing method, so-called normally-off (enhancement type) electrical characteristics can be obtained in a range where the channel length L of the channel region CH is greater than or equal to 2 μm and less than or equal to 4 μm and the channel width of the channel region CH is greater than or equal to 2 μm and less than or equal to 25 μm.

### Third Embodiment

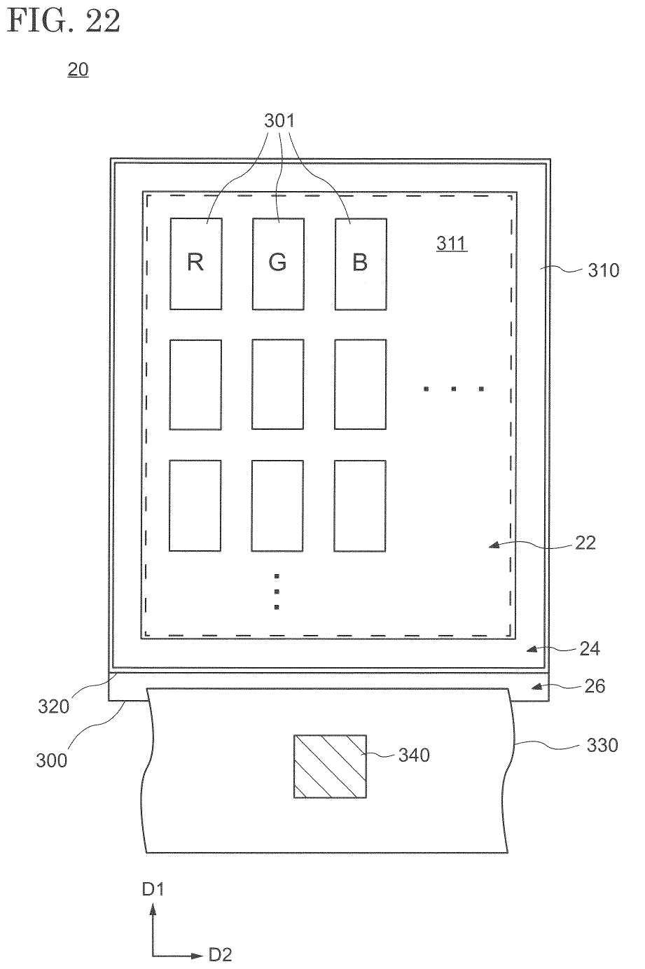

A display device 20 using a semiconductor device 10 according to an embodiment of the present invention is described with reference to FIGS. 22 to 26. In the embodiment shown below, a configuration in which the semiconductor device 10 described in the First Embodiment and the Second Embodiment described above is applied to a circuit of a liquid crystal display device is described.

### [Overview of Display Device 20]

FIG. 22 is a plan view showing an overview of the display device 20 according to an embodiment of the present invention. As is shown in FIG. 22, the display device 20 includes an array substrate 300, a sealing portion 310, a counter substrate 320, a flexible printed circuit substrate 330 (FPC 330), and an IC chip 340. The array substrate 300 and the counter substrate 320 are bonded to each other by the sealing portion 310. A plurality of pixel circuits 301 is arranged in a matrix in a liquid crystal region 22 surrounded by the sealing portion 310. The liquid crystal region 22 is a region overlapping a liquid crystal element 311, which is described later, in a plan view.

A sealing region 24 where the sealing portion 310 is provided is a region surrounding the liquid crystal region 22. The FPC 330 is provided in a terminal region 26. The terminal region 26 is a region where the array substrate 300 is exposed from the counter substrate 320 and is provided outside the sealing region 24. The outside of the sealing region 24 means the outside of the region where the sealing portion 310 is provided and the region surrounded by the sealing portion 310. The IC chip 340 is provided on the FPC 330. The IC chip 340 supplies a signal for driving each pixel circuit 301.

### [Circuit Configuration of Display Device 20]

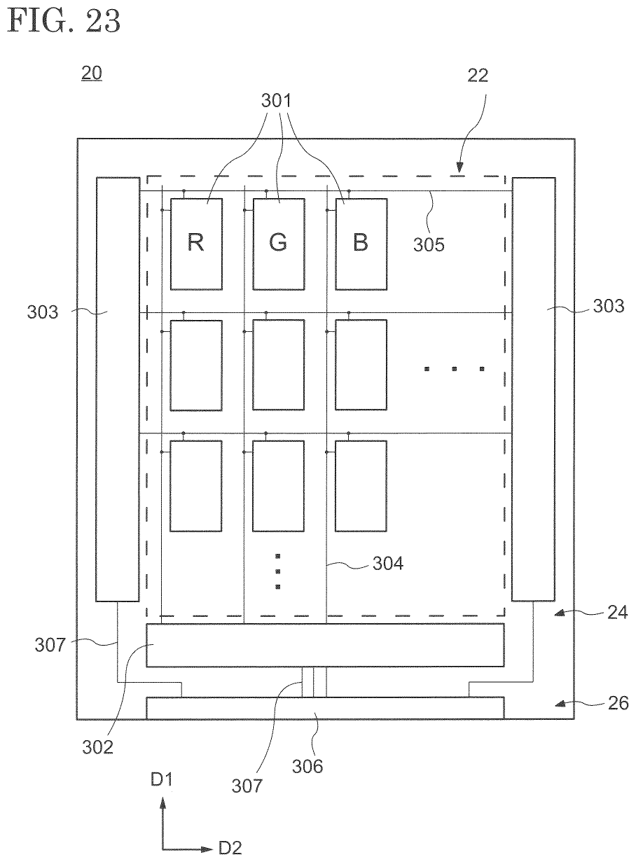

FIG. 23 is a block diagram showing a circuit configuration of the display device 20 according to an embodiment of the present invention. As is shown in FIG. 23, a source driver circuit 302 is arranged at a position adjacent to the liquid crystal region 22 where the pixel circuit 301 is arranged in the direction D1 (column direction), and a gate driver circuit 303 is arranged at a position adjacent to the liquid crystal region 22 in the direction D2 (row direction). The source driver circuit 302 and the gate driver circuit 303 are arranged in the sealing region 24 described above. However, the region where the source driver circuit 302 and the gate driver circuit 303 are arranged is not limited to the sealing region 24. The source driver circuit 302 and the gate driver circuit 303 may be arranged in any region outside the region where the pixel circuit 301 is arranged.

A source wiring 304 extends from the source driver circuit 302 in the direction D1 and is connected to the plurality of pixel circuits 301 arranged in the direction D1. A gate wiring 305 extends from the gate driver circuit 303 in the direction D2 and is connected to the plurality of pixel circuits 301 arranged in the direction D2.

A terminal portion 306 is provided in the terminal region 26. The terminal portion 306 and the source driver circuit 302 are connected to each other by a connection wiring 307. Similarly, the terminal portion 306 and the gate driver circuit 303 are connected to each other by the connection wiring 307. By connecting the FPC 330 to the terminal portion 306, an external device which is connected to the FPC 330 and the display device 20 are connected to each other, and a signal from the external device drives each pixel circuit 301 arranged in the display device 20.

The semiconductor device 10 shown in the First Embodiment and the Second Embodiment is used as a transistor included in the pixel circuit 301, the source driver circuit 302, and the gate driver circuit 303.

### [Pixel Circuit 301 of Display Device 20]

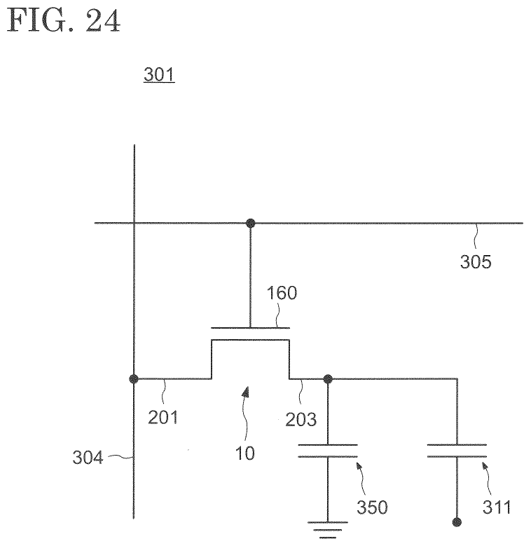

FIG. 24 is a circuit diagram showing a pixel circuit of the display device 20 according to an embodiment of the present invention. As is shown in FIG. 24, the pixel circuit 301 includes elements such as the semiconductor device 10, a storage capacitor 350, and the liquid crystal element 311. The semiconductor device 10 has the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, although an electrode indicated by “201” is referred to as a source electrode and an electrode indicated by “203” is referred to as a drain electrode for the convenience of explanation, the electrode indicated by “201” may function as a drain electrode and the electrode indicated by “203” may function as a source electrode.

### [Cross-Sectional Structure of Display Device 20]

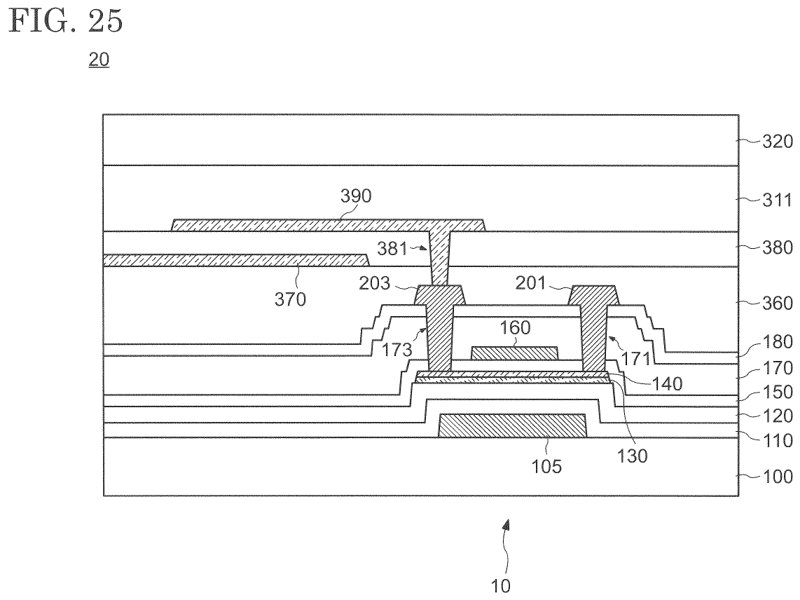

FIG. 25 is a cross-sectional view of the display device 20 according to an embodiment of the present invention. As shown in FIG. 25, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is the same as that of the semiconductor device 10 shown in FIG. 1, the description thereof is omitted.

An insulating layer 360 is provided on the source electrode 201 and the drain electrode 203. A common electrode 370 provided in common for the plurality of pixels is provided on the insulating layer 360. An insulating layer 380 is provided on the common electrode 370. An opening 381 is provided in the insulating layers 360 and 380. A pixel electrode 390 is provided on the insulating layer 380 and inside the opening 381. The pixel electrode 390 is connected to the drain electrode 203.

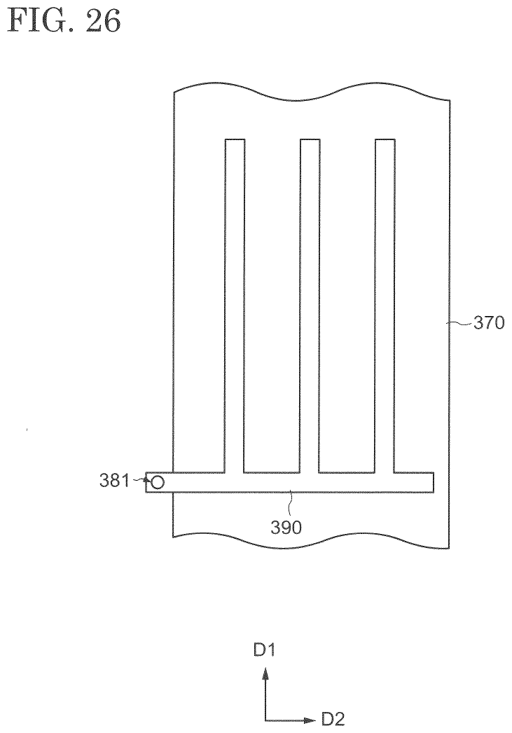

FIG. 26 is a plan view of the pixel electrode 390 and the common electrode 370 of the display device 20 according to an embodiment of the present invention. As shown in FIG. 26, the common electrode 370 has an overlapping region overlapping the pixel electrode 390 in a plan view, and a non-overlapping region not overlapping the pixel electrode 390. When a voltage is supplied between the pixel electrode 390 and the common electrode 370, a transverse electric field is formed from the pixel electrode 390 in the overlapping region toward the common electrode 370 in the non-overlapping region. The gradation of the pixel is determined by the operation of liquid crystal molecules included in the liquid crystal element 311 by the transverse electric field.

### Fourth Embodiment

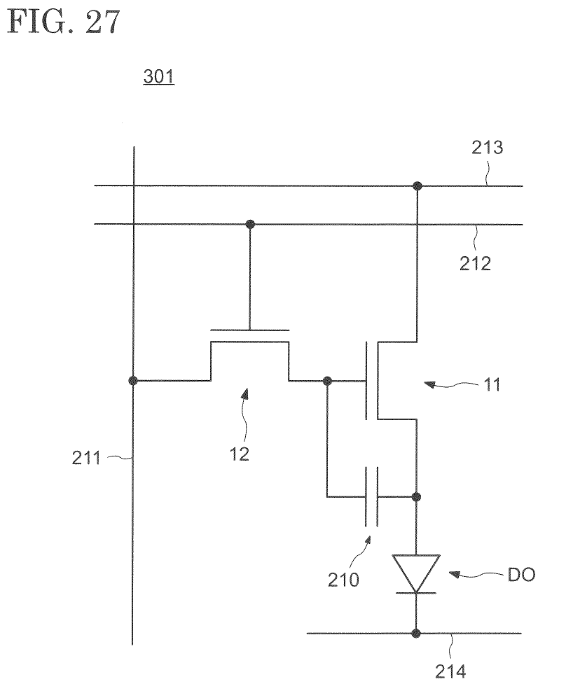

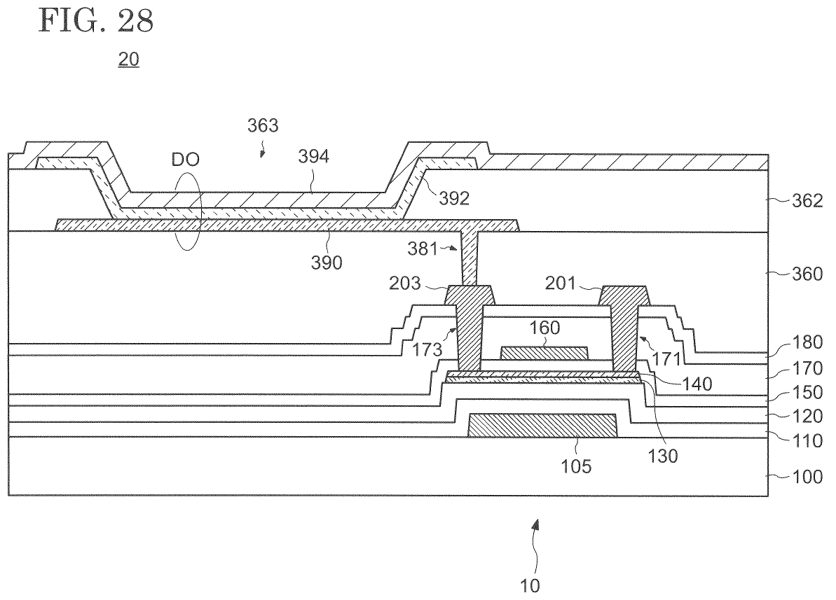

A display device 20 using the semiconductor device 10 according to an embodiment of the present invention is described with reference to FIGS. 27 and 28. In the present embodiment, a configuration in which the semiconductor device 10 described in the First Embodiment and the Second Embodiment is applied to a circuit of an organic EL display device is described. Since the overview and the circuit configuration of the display device 20 are the same as those shown in FIG. 22 and FIG. 23, the description thereof is omitted.

### [Pixel Circuit 301 of Display Device 20]

FIG. 27 is a circuit diagram showing a pixel circuit 301 of the display device 20 according to an embodiment of the present invention. As shown in FIG. 27, the pixel circuit 301 includes elements such as a drive transistor 11, a selection transistor 12, a storage capacitor 210, and a light emitting element DO. The drive transistor 11 and the selection transistor 12 have the same configuration as the semiconductor device 10. The source electrode of the selection transistor 12 is connected to a signal line 211, and the gate electrode of the selection transistor 12 is connected to a gate line 212. The source electrode of the drive transistor 11 is connected to an anode power line 213, and the drain electrode of the drive transistor 11 is connected to one end of the light emitting element DO. The other end of the light emitting element DO is connected to a cathode power line 214. The gate electrode of the drive transistor 11 is connected to the drain electrode of the selection transistor 12. The storage capacitor 210 is connected to the gate electrode and the drain electrode of the drive transistor 11. A gradation signal for determining the light emitting intensity of the light emitting element DO is supplied to the signal line 211. A signal for selecting a pixel row in which the gradation signal described above is written is supplied to the gate line 212.

### [Cross-Sectional Structure of Display Device 20]

FIG. 28 is a cross-sectional diagram of the display device 20 according to an embodiment of the present invention. Although the configuration of the display device 20 shown in FIG. 28 is similar to that of the display device 20 shown in FIG. 25, the structure over the insulating layer 360 of the display device 20 in FIG. 28 is different from the structure over the insulating layer 360 of the display device 20 in FIG. 25. Hereinafter, in the configuration of the display device 20 in FIG. 28, descriptions of the same configuration as the display device 20 in FIG. 25 are omitted, and differences between the two are described.

As shown in FIG. 28, the display device 20 has the pixel electrode 390, a light emitting layer 392, and a common electrode 394 (the light emitting element DO) above the insulating layer 360. The pixel electrode 390 is provided over the insulating layer 360 and inside the opening 381. An insulating layer 362 is provided over the pixel electrode 390. An opening 363 is provided in the insulating layer 362. The opening 363 corresponds to a light emitting region. That is, the insulating layer 362 defines a pixel. The light emitting layer 392 and the common electrode 394 are provided over the pixel electrode 390 exposed by the opening 363. The pixel electrode 390 and the light emitting layer 392 are individually arranged for each pixel. On the other hand, the common electrode 394 is arranged in common for the plurality of pixels. Different materials are used for the light emitting layer 392 depending on the display color of the pixel.

In the Third Embodiment and the Fourth Embodiment, although the configuration in which the semiconductor device 10 described in the First Embodiment and the Second Embodiment is applied to a liquid crystal display device and an organic EL display device is described, the semiconductor device 10 may be applied to display devices (for example, a self-luminous display device or an electronic paper display device other than an organic EL display device) other than these display devices. Further, the semiconductor device 10 described above can be applied without any particular limitation from a small sized display device to a large sized display device.

### Examples

As an Example, the semiconductor device 10 described in the Second Embodiment was fabricated, and an evaluation was performed on the semiconductor device 10. Further, as a Comparative Example, a semiconductor device in which the metal oxide layer 130 in contact with the oxide semiconductor layer 140 was not provided was fabricated.

Further, in the Example, before the gate electrode GE was formed, an aluminum oxide layer was deposited as the metal oxide layer 190 by a sputtering method, and the aluminum oxide layer was removed after the oxidation annealing was performed. On the other hand, in the Comparative Example, the formation of the metal oxide layer 190 and the oxidation annealing were not performed.

### [1. SIMS Analysis]

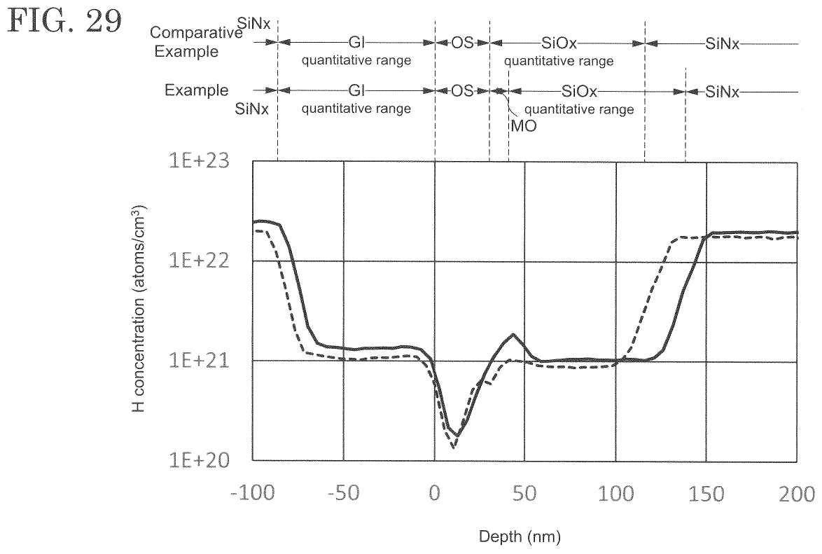

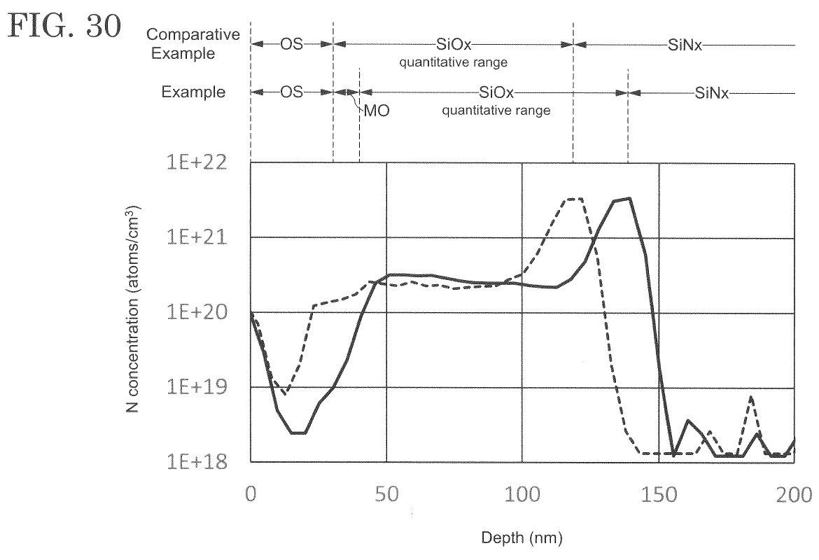

FIGS. 29 and 30 are graphs showing measurement results of a SIMS analysis in the source region or the drain region of the oxide semiconductor layer of the semiconductor device 10. In FIG. 29, the vertical axis indicates a hydrogen concentration (H concentration), and the horizontal axis indicates a depth in a stacking direction of the semiconductor device 10. In FIG. 30, the vertical axis indicates a nitrogen concentration (N concentration), and the horizontal axis indicates a depth in a stacking direction of the semiconductor device 10. Further, FIGS. 29 and 30 show stacking structures of the Example and the Comparative Example in the stacking direction. The symbols SiNx, SiOx, GI, OS, and MO represent the silicon nitride layer, the silicon oxide layer, the gate insulating layer, the oxide semiconductor layer, and the metal oxide layer, respectively. The silicon nitride layer SiNx in contact with the silicon oxide layer SiOx and the silicon oxide layer SiOx correspond to the gate insulating layers 110 and 120, respectively. The metal oxide layer MO, the oxide semiconductor layer OS, the gate insulating layer GI, and the silicon nitride layer SiNx in contact with the gate insulating layer GI correspond to the metal oxide layer 130, the oxide semiconductor layer 140, the gate insulating layer 150, and the insulating layer 170, respectively. In addition, silicon oxide was used for the gate insulating layer GI, similar to the silicon oxide layer SiOx.

In FIGS. 29 and 30, the hydrogen concentration and the nitrogen concentration in the silicon oxide layer SiOx and the gate insulating layer GI was quantified using a SiO₂ standard sample (quantitative range in the figure). That is, in FIGS. 29 and 30, the hydrogen concentration and the nitrogen concentration in each of the silicon oxide layer SiOx and the gate insulating layer GI can be compared using absolute values. On the other hand, although the hydrogen concentrations and the nitrogen concentrations in other layers can be compared in magnitude, the hydrogen concentrations and the nitrogen concentrations in other layers cannot be compared using absolute values.

As shown in FIG. 29, the silicon oxide layer SiOx of the Example (solid line) has a higher hydrogen concentration than the silicon oxide layer SiOx of the Comparative Example (dotted line). The hydrogen concentrations of the silicon oxide layer SiOx of the Example and the Comparative Example are 1.06×10²¹ atoms/cm³ and 8.8×10²⁰ atoms/cm³, respectively. Although the silicon oxide layer SiOx of the Example overlaps the metal oxide layer MO, the silicon oxide layer SiOx of the Comparative Example does not overlap the metal oxide layer MO. That is, the result shown in FIG. 29 means that the hydrogen concentration of the region (the first region) of the silicon oxide layer SiOx that overlaps the metal oxide layer MO is higher than the hydrogen concentration of the region (the second region) of the silicon oxide layer SiOx that does not overlap the metal oxide layer MO. Since hydrogen diffused into the silicon oxide layer SiOx is blocked by the metal oxide layer MO, the hydrogen concentration is high in the first region.

Further, as shown in FIG. 30, the silicon oxide layer SiOx of the Example (solid line) has a higher nitrogen concentration than the silicon oxide layer SiOx of the Comparative Example (dotted line). The nitrogen concentrations of the silicon oxide layer SiOx of the Example and the Comparative Example are 3.2×10²⁰ atoms/cm³ and 2.4×10²⁰ atoms/cm³, respectively. Although the silicon oxide layer SiOx of the Example overlaps the metal oxide layer MO, the silicon oxide layer SiOx of the Comparative Example does not overlap the metal oxide layer MO. That is, the result shown in FIG. 30 means that the nitrogen concentration of the region (the first region) of the silicon oxide layer SiOx that overlaps the metal oxide layer MO is higher than the nitrogen concentration of the region (the second region) of the silicon oxide layer SiOx that does not overlap the metal oxide layer MO. Since the nitrogen diffused into the silicon oxide layer SiOx is blocked by the metal oxide layer MO, the nitrogen concentration is high in the first region. In addition, the nitrogen concentration in the first region increased from the substrate toward the metal oxide layer MO.

### [2. Electrical Characteristics]

When the electrical characteristics of the semiconductor devices of the Example and the Comparative Example were measured, the mobility of the semiconductor device 10 of the Example exceeded 40 cm²/Vs, whereas the mobility of the semiconductor device of the Comparative Example was less than or equal to 30 cm²/Vs. Further, when the reliability test of the semiconductor device 10 of the Example was measured, the electrical characteristics hardly changed in both the Negative Bias Temperature Illumination Stress (NBTIS) test and the Positive Bias Temperature Stress (PBTS) test.

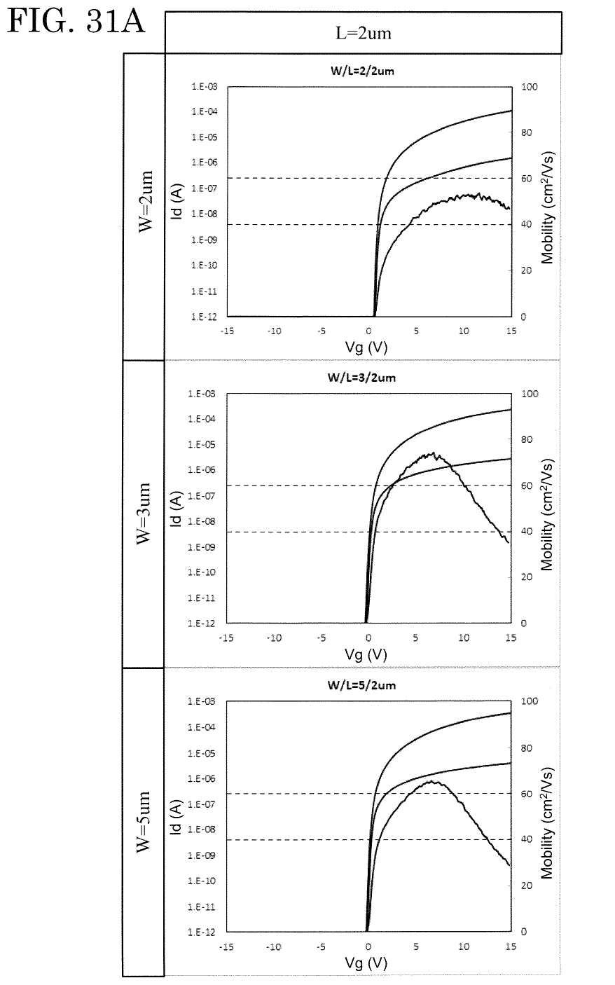

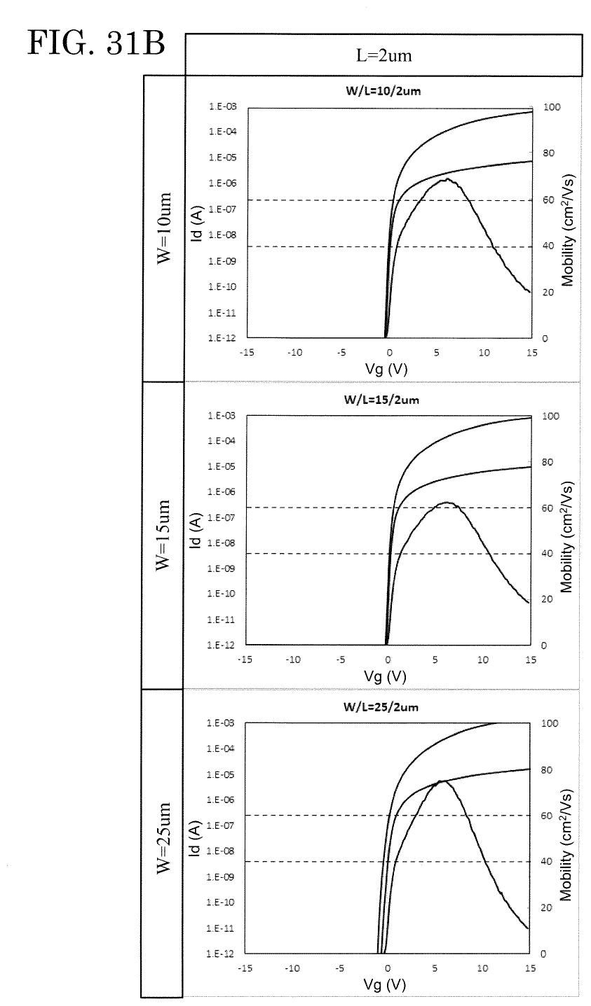

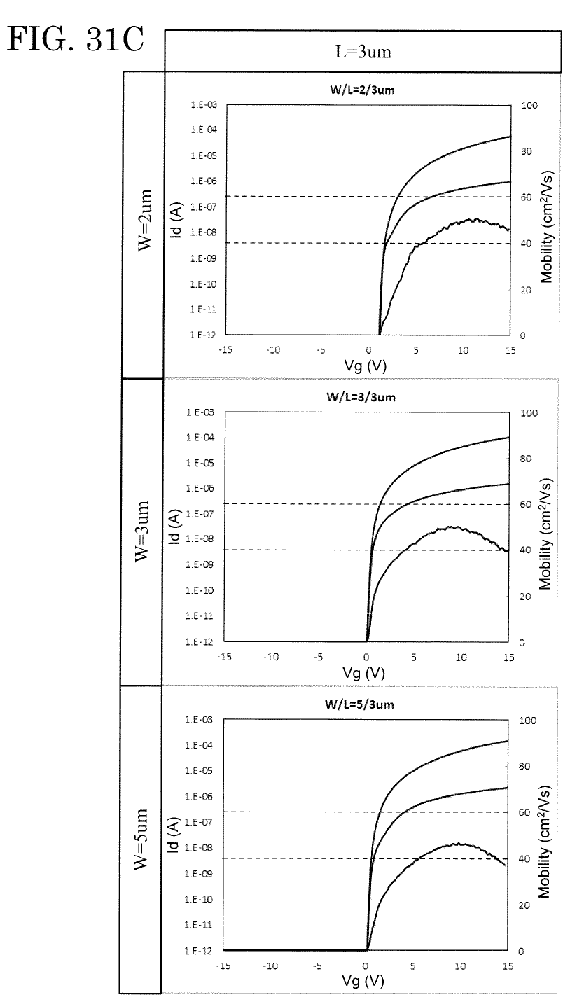

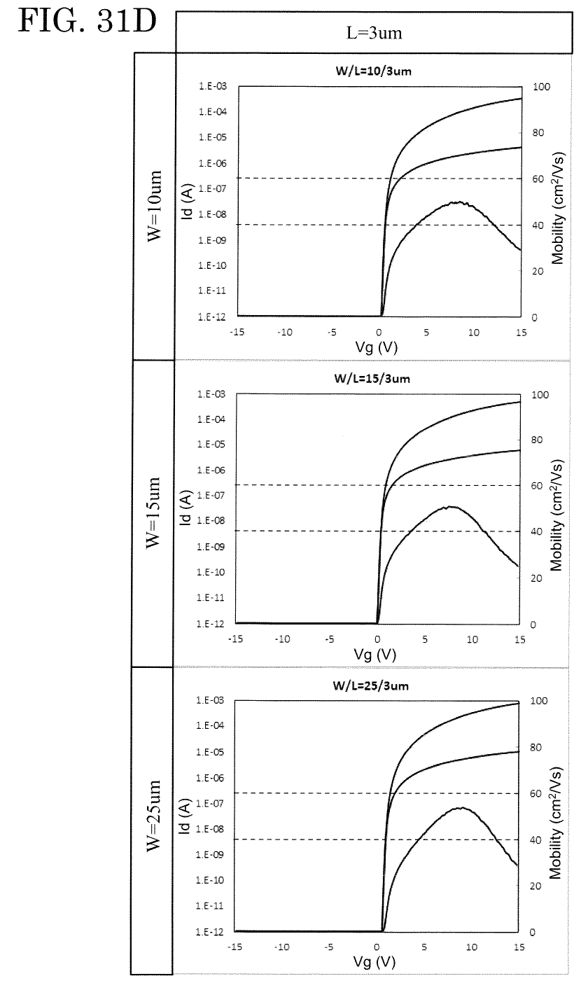

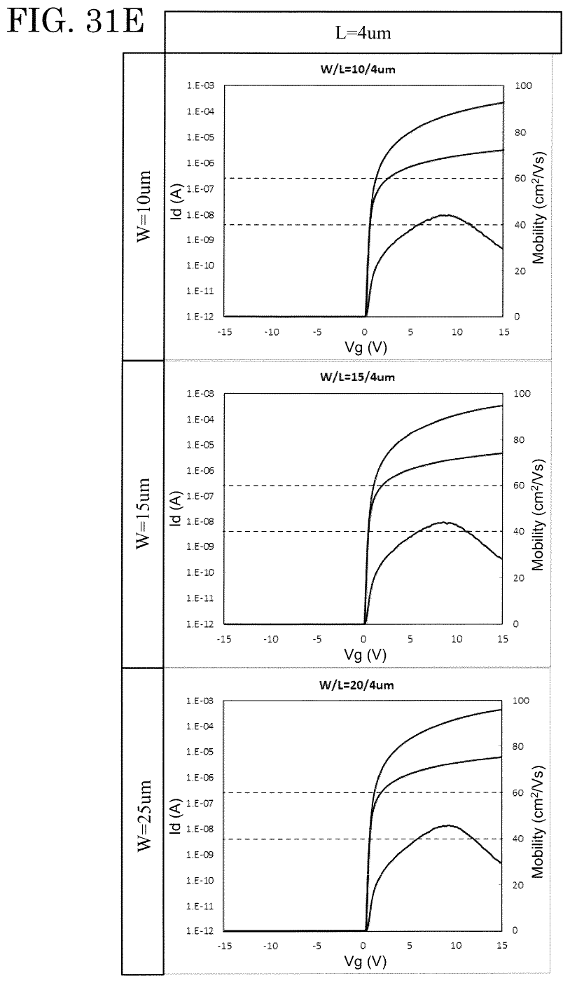

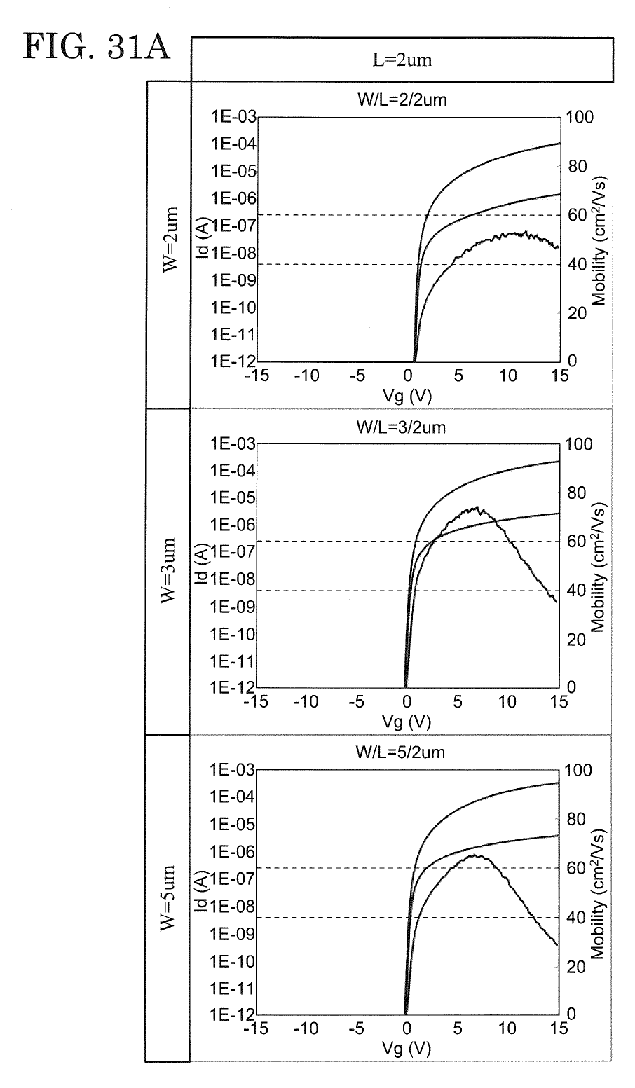

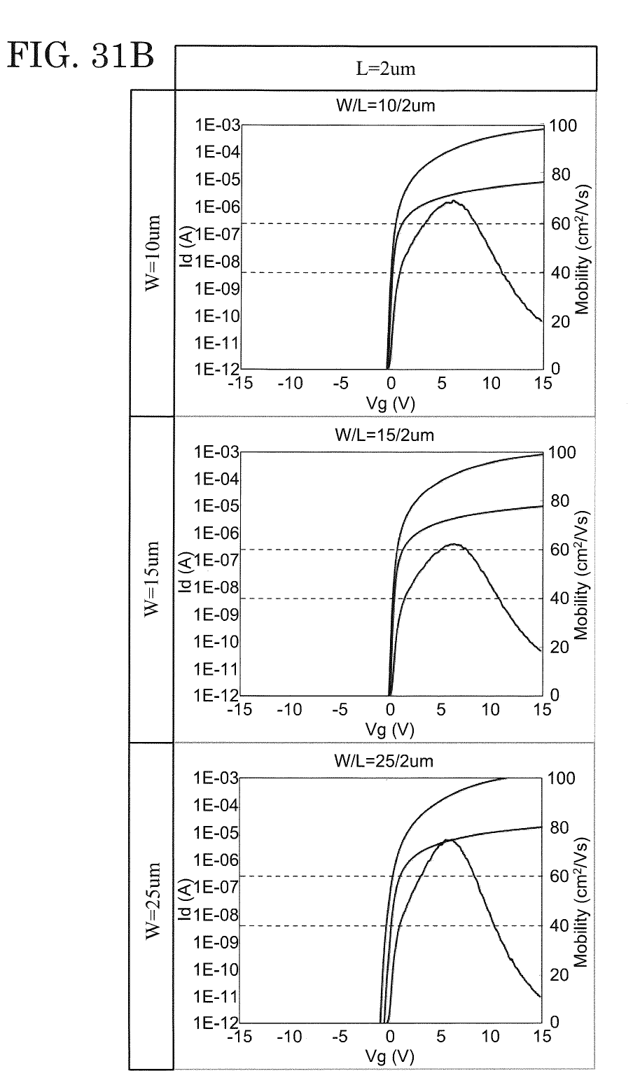

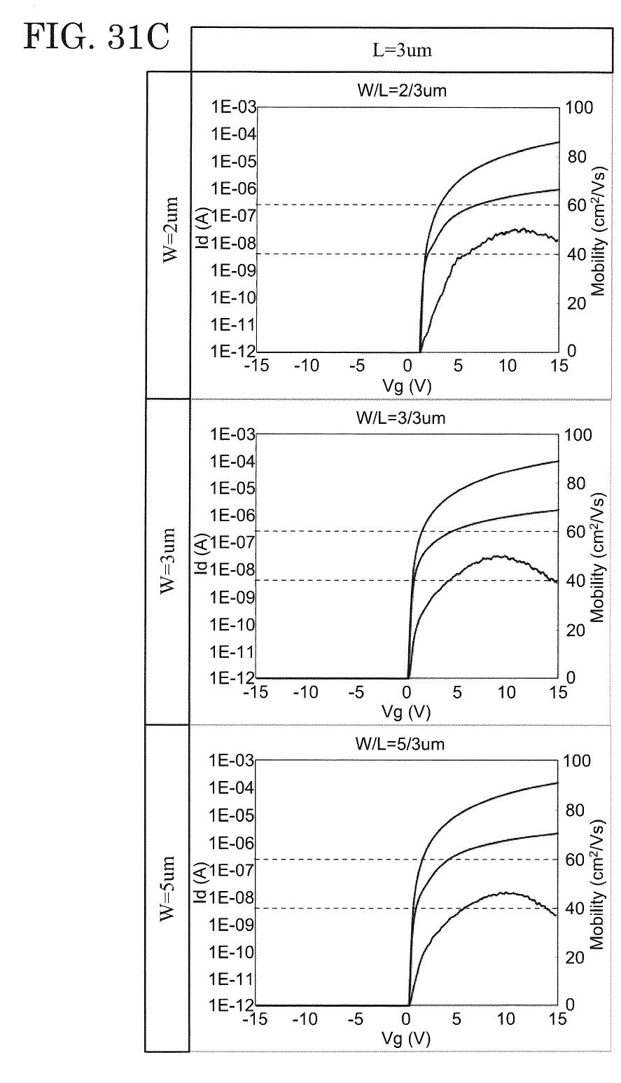

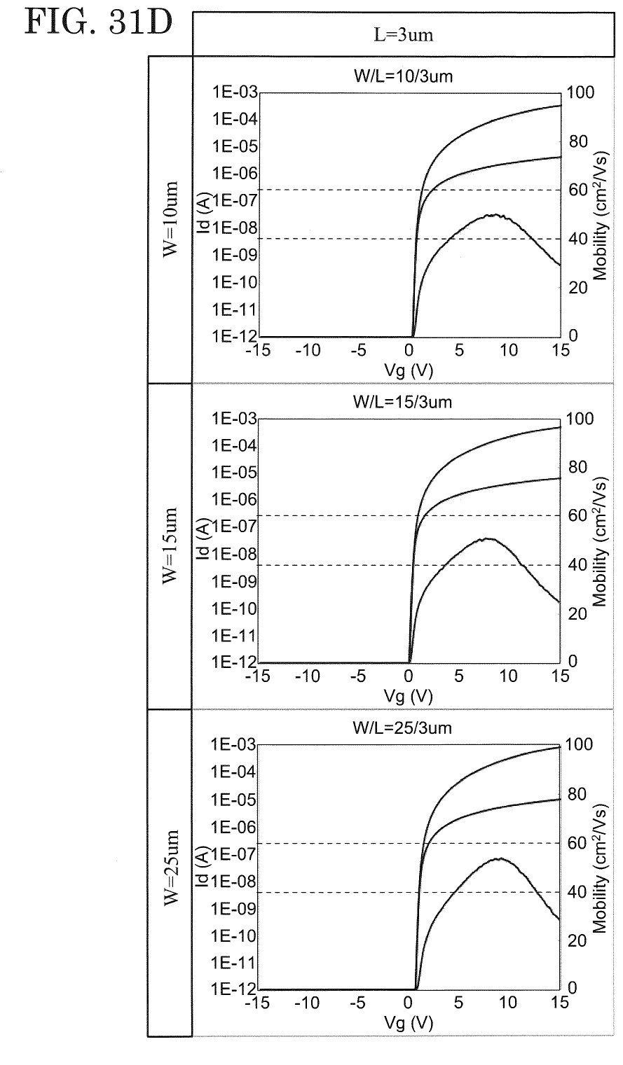

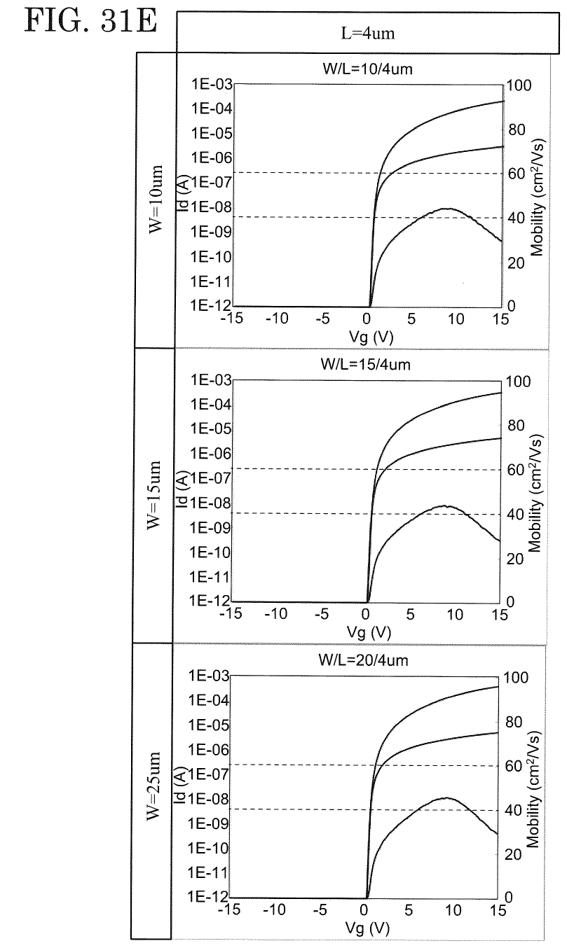

FIGS. 31A to 31E show graphs of electrical characteristics of semiconductor devices 10 having different channel lengths L and channel widths W in the Example. Specifically, FIG. 31A to FIG. 31E show electrical characteristics (Id-Vg characteristics) and mobility of semiconductor devices 10 having channel lengths L of 2 μm to 4 μm and channel widths W of 2 μm to 25 μm. The vertical axis for drain current (Id) is shown on the left side of each graph, and the vertical axis for mobility calculated from the drain current is shown on the right side of each graph. Table 1 shows the measurement conditions for the electrical characteristics shown in FIGS. 31A to 31E.

TABLE 1

| | |
|---|---|
| Source-Drain Voltage | 0.1 V, 10 V |
| Gate Voltage | −15 V to +15 V |
| Measurement Environment | Room Temperature, Dark Room |

As shown in FIGS. 31A to 31E, in the semiconductor devices 10 of the Example, good electrical characteristics are obtained even when the channel width W relative to the channel length L is large, and no size dependency (W/L size dependency) is confirmed. Further, the mobility of the semiconductor devices 10 of the Example exceeds 40 cm²/Vs in all W/L sizes. In the semiconductor devices 10 with some of W/L sizes, the mobility greater than or equal to 60 cm²/Vs is obtained.

According to the above-described Example, it is considered that in the semiconductor device 10 of the Example, the diffusion of hydrogen and nitrogen into the oxide semiconductor layer OS is suppressed by the blocking function of the metal oxide layer MO, and impurities in the oxide semiconductor layer OS are reduced. That is, in the semiconductor device 10 of the Example, the crystallinity of the oxide semiconductor layer OS is improved and impurity scattering in the oxide semiconductor layer OS is reduced, so that mobility and reliability are improved. Further, the film quality of the oxide semiconductor layer OS is improved due to the reduction in hydrogen and nitrogen in the oxide semiconductor layer OS, and the semiconductor device 10 does not exhibit size dependency (W/L size dependency).

Each of the embodiments described above as the embodiments of the present invention can be appropriately combined and implemented as long as no contradiction is caused. Further, the addition, deletion, or design change of components, or the addition, deletion, or condition change of processes as appropriate by those skilled in the art based on each of embodiments are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a substrate;
an insulating layer over the substrate;
a metal oxide layer over the insulating layer; and
an oxide semiconductor layer over the metal oxide layer,
wherein the insulating layer comprises:
a first region overlapping the metal oxide layer, and
a second region not overlapping the metal oxide layer,
a hydrogen concentration of the first region is greater than a hydrogen concentration of the second region, and
a nitrogen concentration of the first region is greater than a nitrogen concentration of the second region.

2. The semiconductor device according to claim 1, wherein the nitrogen concentration of the first region increases from the substrate toward the metal oxide layer.

3. The semiconductor device according to claim 1, wherein the metal oxide layer is in contact with the insulating layer.

4. The semiconductor device according to claim 1, wherein the metal oxide layer is in contact with the oxide semiconductor layer.

5. The semiconductor device according to claim 1, wherein the metal oxide contains aluminum oxide.

6. The semiconductor device according to claim 1, wherein the insulating layer contains silicon oxide.

7. The semiconductor device according to claim 1,
wherein the oxide semiconductor layer contains two or more metal elements including indium, and
a ratio of the indium to the two or more metal elements is greater than or equal to 50%.

8. The semiconductor device according to claim 1, wherein the oxide semiconductor layer has crystallinity.

9. The semiconductor device according to claim 1, wherein a field effect mobility is greater than or equal to 30 cm²/Vs.
